(19) United States
(12) Patent Application Publication
(10) Pub. No.: US 2026/0164934 A1
(43) Pub. Date: Jun. 11, 2026

(54) DISPLAY DEVICE, ELECTRONIC DEVICE INCLUDING THE SAME, AND METHOD OF MANUFACTURING THE SAME

(71) Applicant: Samsung Display Co., Ltd., Yongin-si (KR)

(72) Inventor: YOUNGJAE JEON, Yongin-si (KR)

(21) Appl. No.: 19/179,756

(22) Filed: Apr. 15, 2025

(30) Foreign Application Priority Data
Jul. 1, 2024 (KR) 10-2024-0085932

(51) Int. Cl. H10K 59/121; H10K 59/12

(52) U.S. Cl. CPC H10K 59/1213; H10K 59/1201

(57) ABSTRACT

A display device includes: a base substrate; a conductive pattern on the base substrate; a buffer pattern on the conductive pattern; a transistor on the buffer pattern and including a semiconductor pattern, a source electrode, a drain electrode, and a gate electrode; and a light emitting element including a first electrode, a light emitting layer, and a second electrode on the transistor and electrically connected to the transistor, wherein the semiconductor pattern includes a source area contacting the source electrode, a drain area spaced apart from the source area and contacting the drain electrode, and a channel area between the source area and the drain area, and wherein, in a plan view, the semiconductor pattern overlaps the buffer pattern.

### CROSS-REFERENCE TO RELATED APPLICATION

The present application claims priority to and the benefit of Korean Patent Application No. 10-2024-0085932, filed on Jul. 1, 2024, in the Korean Intellectual Property Office, the entire disclosure of which is incorporated herein by reference.

### BACKGROUND

Aspects of some embodiments of the present disclosure described herein relate to a method of manufacturing a display device, an electronic device including the same, and a display device manufactured through the same.

Multimedia devices such as televisions, mobile phones, tablets, computers, navigation devices, and game consoles may be provided with display panels for displaying images. The display panel may include a plurality of pixels for displaying images, and each of the pixels may include a light emitting element that generates a light and a driving element connected to the light emitting element.

The light emitting element and the driving element of the display panel may be formed through lamination of thin films and patterning of the thin films using a mask. Because a lot of costs are required for a process of manufacturing the display panel using the mask, it may be desirable to simplify the process of manufacturing the display panel and to reduce the number of masks required for manufacturing the display device. Further, it may be desirable to manufacture the display panel having reliability while the process is simplified.

The above information disclosed in this Background section is only for enhancement of understanding of the background and therefore the information discussed in this Background section does not necessarily constitute prior art.

### SUMMARY

Aspects of some embodiments of the present disclosure include a display device manufactured by a simplified manufacturing method and capable of implementing high resolution.

According to some embodiments of the present disclosure, a method of manufacturing a display device includes forming a first conductive layer, a buffer layer, and a second conductive layer on a base substrate including a display area and a non-display area around the display area, forming a first photoresist pattern by ashing a first photoresist layer using a mask, forming a conducive pattern, a buffer pattern, and a semiconductor pattern through a first etching operation of etching the first conductive layer, the buffer layer, and the second conductive layer using the first photoresist pattern, forming a preliminary gate insulating layer and a third conductive layer on the semiconductor pattern and the buffer pattern, forming a second photoresist pattern by ashing a second photoresist layer, and forming a gate electrode and a gate insulating layer through a second etching operation of etching the third conductive layer and the preliminary gate insulating layer using the second photoresist pattern.

According to some embodiments, the first etching operation may include a (1-1)^{th} etching operation of etching the second conductive layer, and the (1-1)^{th} etching operation may correspond to wet etching.

According to some embodiments, the first etching operation may include an operation of etching the first photoresist pattern and a (1-2)^{th} etching operation of etching the buffer layer, and the (1-2)^{th} etching operation may correspond to dry etching.

According to some embodiments, the first etching operation may include a (1-3)^{th} etching operation of etching the first conductive layer, and the (1-3)^{th} etching operation may correspond to wet etching.

According to some embodiments, the mask may include a transmissive part that transmits a light, a light shielding part that shields a light, and a semi-transmissive part having light transmittance smaller than that of the transmissive part, and the first photoresist pattern may include a first part patterned by the light shielding part and a second part patterned by the semi-transmissive part, and a height of the first part may be greater than a height of the second part.

According to some embodiments, the semiconductor pattern may overlap the first part of the first photoresist pattern.

According to some embodiments, the second etching operation may include a (2-1)^{th} etching operation of etching the third conductive layer and a (2-2)^{th} etching operation of etching the preliminary gate insulating layer, the (2-1)^{th} etching operation may correspond to wet etching, and the (2-2)^{th} etching operation may correspond to dry etching.

According to some embodiments, the method may further include n+ doping the semiconductor pattern exposed by the gate insulating layer through the (2-2)^{th} etching operation.

According to some embodiments, the method may further include forming a first preliminary insulating layer that covers the gate electrode, forming a third photoresist pattern by ashing a third photoresist layer, and forming a first insulating layer through a third etching operation of etching the first preliminary insulating layer using the third photoresist pattern.

According to some embodiments, the third etching operation may correspond to dry etching.

According to some embodiments, the method may further include forming a third conductive layer in contact with the semiconductor pattern on the first insulating layer, forming a fourth photoresist pattern by ashing a fourth photoresist layer, and forming a source electrode and a drain electrode in contact with the semiconductor pattern through a fourth etching operation of etching the third conductive layer using the fourth photoresist pattern.

According to some embodiments, the forming of the source electrode and the drain electrode in contact with the semiconductor pattern may include forming a pad on the non-display area.

According to some embodiments, the fourth etching operation may correspond to wet etching.

According to some embodiments, the forming of the gate electrode and the gate insulating layer may include forming a first conductive pattern, the forming of the source electrode and the drain electrode may include forming a second conductive pattern, and the first conductive pattern and the second conductive pattern may form a capacitor.

According to some embodiments, the method may further include forming a second preliminary insulating layer that covers the first insulating layer, the source electrode, and the drain electrode, forming a third preliminary insulating layer on the second preliminary insulating layer, forming a fifth photoresist pattern by ashing a fifth photoresist layer, and forming a second insulating layer and a third insulating layer through a fifth etching operation of etching the second preliminary insulating layer and the third preliminary insulating layer using the fifth photoresist pattern.

According to some embodiments, the forming of the second preliminary insulating layer may include depositing an inorganic material, and the forming of the third preliminary insulating layer may include depositing an organic material.

According to some embodiments, the fifth etching operation may correspond to dry etching.

According to some embodiments, the method may further include forming a light emitting element including a first electrode, a light emitting layer, and a second electrode on the third insulating layer.

According to some embodiments of the present disclosure, a display device includes a base substrate, a conductive pattern on the base substrate, a buffer pattern on the conductive pattern, a transistor on the buffer pattern and including a semiconductor pattern, a source electrode, a drain electrode, and a gate electrode; and a light emitting element including a first electrode, a light emitting layer, and a second electrode arranged on the transistor and electrically connected to the transistor. According to some embodiments, the semiconductor pattern includes a source area in contact with the source electrode, a drain area spaced apart from the source area and in contact with the drain electrode, and a channel area formed between the source area and the drain area, and in a plan view, the semiconductor pattern overlaps the buffer pattern.

According to some embodiments, the display device may further include a first conductive pattern including the same material as the source electrode and the drain electrode and formed through the same process, and a second conductive pattern including the same material as the gate electrode and formed through the same process, wherein the first conductive pattern and the second conductive pattern may form a capacitor.

According to some embodiments of the present disclosure, an electronic device includes a display device configured to display an image; and a processor configured to control the display device to display the image. The display device includes a base substrate, a conductive pattern on the base substrate, a buffer pattern on the conductive pattern, a transistor on the buffer pattern and including a semiconductor pattern, a source electrode, a drain electrode, and a gate electrode; and a light emitting element including a first electrode, a light emitting layer, and a second electrode arranged on the transistor and electrically connected to the transistor. According to some embodiments, the semiconductor pattern includes a source area in contact with the source electrode, a drain area spaced apart from the source area and in contact with the drain electrode, and a channel area formed between the source area and the drain area, and in a plan view, the semiconductor pattern overlaps the buffer pattern.

### BRIEF DESCRIPTION OF THE DRAWINGS

The above and other aspects and features of embodiments according to the present disclosure will become more apparent by describing in more detail aspects of some embodiments thereof with reference to the accompanying drawings.

FIG. 1 is a perspective view of a display device according to some embodiments of the present disclosure.

FIG. 2 is an exploded perspective view of the display device according to some embodiments of the present disclosure.

FIG. 3 is a cross-sectional view of a display module according to some embodiments of the present disclosure.

FIG. 4A is a plan view of a display panel according to some embodiments of the present disclosure.

FIG. 4B is an equivalent circuit diagram of a pixel according to some embodiments of the present disclosure.

FIG. 5 is an enlarged plan view of a display area according to some embodiments of the present disclosure.

FIG. 6 is a cross-sectional view of a portion of the display device according to some embodiments of the present disclosure.

FIGS. 7A to 7L are cross-sectional views illustrating some of operations of a method for manufacturing a display device according to some embodiments of the present disclosure.

FIG. 8 is a block diagram illustrating an electronic device according to some embodiments of the present disclosure.

### DETAILED DESCRIPTION

In the specification, the expression that a first component (or area, layer, part, portion, etc.) is “located on”, “connected with” or “coupled to” a second component means that the first component is directly located on/connected with/coupled to the second component or means that a third component is interposed therebetween.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Hereinafter, aspects of some embodiments of the present disclosure will be described in more detail with reference to the accompanying drawings.

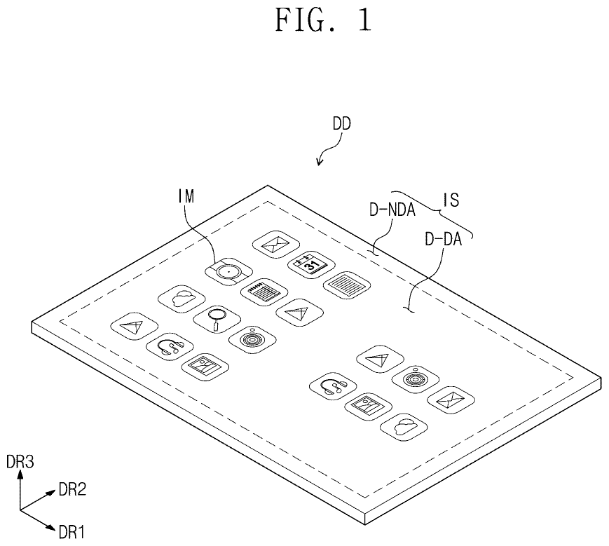

FIG. 1 is a perspective view of a display device DD according to some embodiments of the present disclosure.

The display device DD may be a device that is activated by an electric signal and display an image IM. The display device DD may provide or display the image IM to a user. For example, the display device DD may be a large-sized device such as a television and an external billboard as well as a small or medium-sized device such as a monitor, a mobile phone, a tablet, a navigation device, and a game console. Meanwhile, the display device DD is illustrative, and the display device DD is not limited to any particular embodiment as long as embodiments do not deviate from the concept of the present disclosure.

Referring to FIG. 1, the display device DD may have a rectangular shape including long sides extending in a first direction DR1 and short sides extending in a second direction DR2 on a plane (e.g., in a plan view or a view from a direction perpendicular or normal with respect to a plane defined by the first direction DR1 and the second direction DR2). However, embodiments according to the present disclosure are not limited thereto, and the display device DD may have various shapes such as a circular shape, an elliptical shape, an oval shape, an irregular shape, or a polygonal shape rather than a rectangular shape on a plane (e.g., in a plan view).

The display device DD may display the image IM in a third direction DR3 through a display surface IS parallel to a surface defined by the first direction DR1 and the second direction DR2. The third direction DR3 may be parallel (or substantially parallel) to a normal direction of the display surface IS. The display surface IS on which the image IM is displayed may correspond to a front surface of the display device DD. The image IM may include a still image as well as a dynamic image. FIG. 1 illustrates icon images as an example of the image IM.

FIG. 1 illustratively illustrates the display device DD having the flat display surface IS. However, embodiments according to the present disclosure are not limited thereto, and the display surface IS of the display device DD may further include a curved surface bent from a flat surface.

According to some embodiments, front surfaces (or upper surfaces) and rear surfaces (or lower surfaces) of members constituting the display device DD may be defined based on the third direction DR3. The front surface and the rear surface may be opposite to each other in the third direction DR3 and a normal direction of the front surface and the rear surface may be parallel to the third direction DR3. A separation distance between the front surface and the rear surface defined in the third direction DR3 may correspond to a thickness of the member.

In the specification, the phrases “on a plane” or “in a plan view” may be defined as a state of being viewed from the third direction DR3. In the specification, the phrase “on a cross section” may be defined as a state of being viewed in the first direction DR1 or the second direction DR2. However, the directions indicated by the first to third directions DR1, DR2, and DR3 are relative concepts and may be changed to other directions.

The display device DD may be flexible. The wording “flexible” may mean a bendable property and include a completely folded structure to a structure that may be bent by several nanometers. For example, the flexible display device DD may include a curved device, a rollable device, a slidable device, or a foldable device. However, embodiments according to the present disclosure are not limited thereto, and the display device DD may be rigid.

The display surface IS of the display device DD may include a display unit D-DA and a non-display unit D-NDA. The display unit D-DA may be a part inside a front surface of the display device DD on which the image IM is displayed, and the user may visually recognize the image IM through the display unit D-DA. FIG. 1 illustratively illustrates the display unit D-DA having a quadrangular shape on a plane (e.g., in a plan view), but the shape of the display unit D-DA may be variously changed depending on design of the display device DD.

The non-display unit D-NDA may be a part inside the front surface of the display device DD, on which the image IM is not displayed. The non-display unit D-NDA may be a part having a color (e.g., a set or predetermined color) and shielding a light. The non-display unit D-NDA may be adjacent to (e.g., in a periphery or outside a footprint of) the display unit D-DA. For example, the non-display unit D-NDA may be located outside the display unit D-DA and surround the display unit D-DA. However, this is illustratively illustrated, the non-display unit D-NDA may be adjacent to only one side of the display unit D-DA or located on a side surface rather than the front surface of the display device DD, but embodiments according to the present disclosure are not limited thereto, and the non-display unit D-NDA may be omitted.

The display device DD may detect an external input applied from the outside. The external input may have various forms such as pressure, temperature, and light provided from the outside. The external input may include an input (e.g., contact by a hand of the user or a pen) in contact with the display device DD as well as an input (e.g., hovering) applied in proximity to the display device DD.

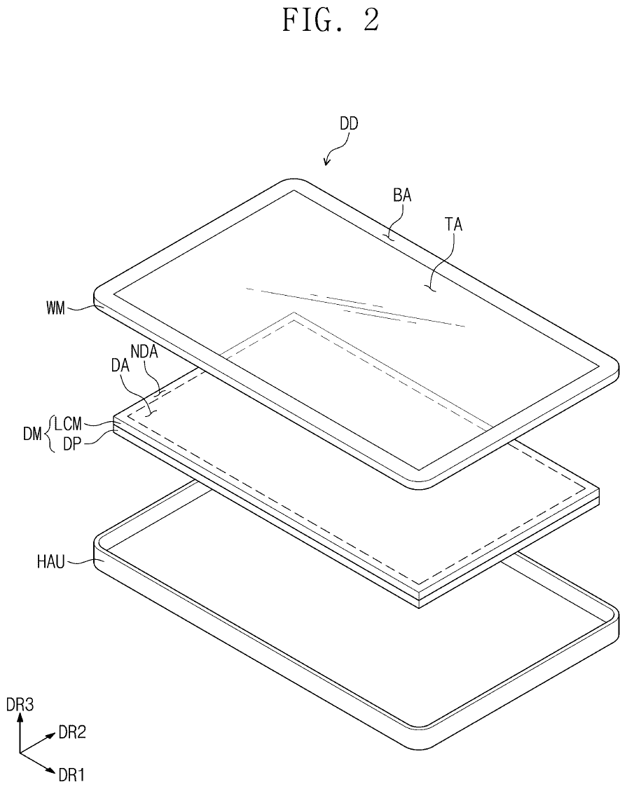

FIG. 2 is an exploded perspective view of the display device DD according to some embodiments of the present disclosure.

Referring to FIG. 2, the display device DD may include a window WM, a display module DM, and a housing HAU.

The window WM and the housing HAU may be coupled to each other to constitute an exterior of the display device DD and provide an internal space in which components of the display device DD, such as the display module DM, may be accommodated.

The window WM may be located on the display module DM. The window WM may protect the display module DM from an external impact. A front surface of the window WM may correspond to the display surface IS (see FIG. 1) of the display device DD. The front surface of the window WM may include a transmissive area TA and a bezel area BA.

The transmissive area TA of the window WM may be an optically transparent area. The window WM may transmit an image provided by the display module DM through the transmissive area TA, and the user may visually recognize the image. The transmissive area TA may correspond to the display unit D-DA (see FIG. 1) of the display device DD.

The window WM may include an optically transparent insulating material. For example, the window WM may include glass, sapphire, or plastic. The window WM may have a single-layer structure or a multi-layer structure. The window WM may further include functional layers, such as a fingerprint preventing layer, a phase control layer, and/or a hard coating layer which are arranged on an optically transparent substrate.

The bezel area BA of the window WM may be provided as an area on which a material having a color (e.g., a set or predetermined color) is deposited, coated, or printed on a transparent substrate. The bezel area BA of the window WM may prevent or reduce instances of one component of the display module DM arranged to overlap the bezel area BA being visually recognized from the outside. The bezel area BA may correspond to the non-display unit D-NDA (see FIG. 1) of the display device DD.

The display module DM may be located between the window WM and the housing HAU. The display module DM may display an image according to an electric signal. The display module DM may include a display area DA and a non-display area NDA around (e.g., in a periphery or outside a footprint of) the display area DA.

The display area DA may be an area that is activated by an electric signal and outputs an image. The display area DA of the display module DM may overlap the transmissive area TA of the window WM. Meanwhile, in the specification, the wording “an area/part and an area/part overlap each other” is not limited to a state in which the area/part and the area/part have the same area and/or the same shape. The image output from the display area DA may be visually recognized from the outside through the transmissive area TA.

The non-display area NDA may be adjacent to (e.g., in a periphery or outside a footprint of) the display area DA. For example, the non-display area NDA may surround (e.g., in a periphery or outside a footprint of) the display area DA. However, embodiments according to the present disclosure are not limited thereto, and the non-display area NDA may be defined in various shapes. The non-display area NDA may be an area in which a driving circuit for driving elements arranged in the display area DA, signal lines for providing electrical signals to the elements, and pads are arranged. The non-display area NDA of the display module DM may overlap the bezel area BA of the window WM, and visibility of components arranged in the non-display area NDA from the outside by the bezel area BA may be prevented or reduced.

The housing HAU may be located under the display module DM and accommodate the display module DM. The housing HAU may protect the display module DM by absorbing an impact applied from the outside to the display module DM and preventing or reducing instances of foreign substances/moisture or contaminants penetrating into the display module DM. According to some embodiments, the housing HAU may be provided in the form in which a plurality of storage members are coupled.

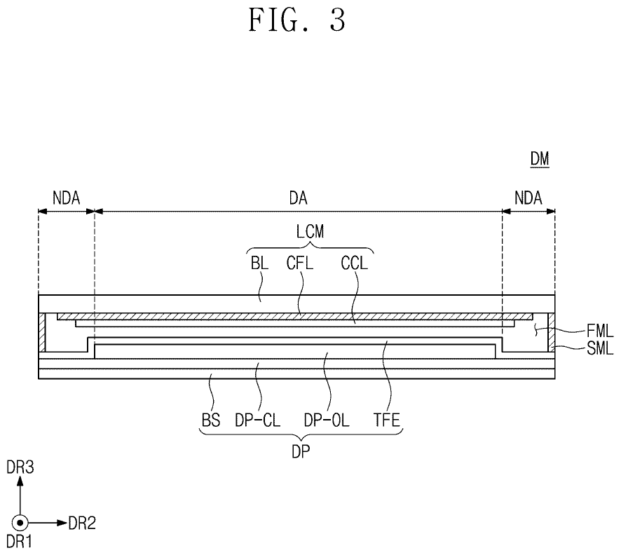

FIG. 3 is a cross-sectional view of the display module DM according to some embodiments of the present disclosure.

Referring to FIGS. 2 and 3, the display module DM may include a display panel DP and a light control member LCM located on the display panel DP.

The display panel DP according to some embodiments may be a light emitting display panel, but embodiments according to the present disclosure are not particularly limited thereto. For example, the display panel DP may be an organic light emitting display panel, an inorganic light emitting display panel, or a quantum dot light emitting display panel. A light emitting layer of the organic light emitting display panel may include an organic light emitting material, and a light emitting layer of the inorganic light emitting display panel may include an inorganic light emitting material. A light emitting layer of the quantum dot light emitting display panel may include a quantum dot and a quantum rod. Hereinafter, the display panel DP will be described as the organic light emitting display panel.

The display panel DP may include a base substrate BS, a circuit layer DP-CL, a display element layer DP-OL, and an encapsulation layer TFE.

The base substrate BS may provide a base surface on which the circuit layer DP-CL is located. The base substrate BS may be a rigid substrate or a flexible substrate. The base substrate BS may include a glass or synthetic resin layer. The synthetic resin layer may include a thermosetting resin. For example, the synthetic resin layer may be a polyimide-based resin layer, and a material thereof is not particularly limited thereto. The synthetic resin layer may include at least one of an acrylic resin, a methacrylic resin, a polyisoprene, a vinyl resin, an epoxy resin, a urethane resin, a cellulose resin, a siloxane resin, a polyamide resin, or a perylene resin. In addition, the base substrate BS may include a glass substrate, a metal substrate, or an organic/inorganic composite material substrate.

The circuit layer DP-CL may be located on the base substrate BS. The circuit layer DP-CL may include driving elements such as transistors, signal lines, and pads. The circuit layer DP-CL may be located on the base substrate BS. The circuit layer DP-CL may include an insulating layer, a semiconductor pattern, a conductive pattern, a signal line, and the like. The insulating layer, a semiconductor layer, and a conductive layer may be formed on the base substrate BS by a method such as coating or deposition, and the insulating layer, the semiconductor layer, and the conductive layer may be selectively patterned through a plurality of photolithography processes. Accordingly, the semiconductor pattern, the conductive pattern, and the signal line may be formed on the circuit layer DP-CL. The circuit layer DP-CL may include a transistor, a buffer layer, and a plurality of insulating layers.

The display element layer DP-OL may include light emitting elements arranged to overlap the display area DA. The light emitting elements of the display element layer DP-OL may be electrically connected to the driving elements of the circuit layer DP-CL and may output lights through the display area DA according to signals of the driving elements.

The encapsulation layer TFE may be located on the display element layer DP-OL to seal the light emitting elements. The encapsulation layer TFE may include thin films for relatively improving optical efficiency of the light emitting elements or protecting the light emitting elements.

The light control member LCM may be located on the display panel DP. The light control member LCM may be manufactured through a manufacturing process separate from a process of manufacturing the display panel DP and coupled onto the display panel DP. For example, the light control member LCM may be provided on the display panel DP and then coupled to the display panel DP through a bonding process using a sealing member SML.

However, embodiments according to the present disclosure are not limited thereto, and the light control member LCM may be directly located on the display panel DP. In the specification, a state in which components are formed by a continuous process without a separate adhesive layer or a separate adhesive member located therebetween may be expressed as “directly located.” For example, the expression “the light control member LCM is directly located on the display panel DP” may indicate a state in which, after the display panel DP is formed, the light control member LCM is formed on the base surface provided by the display panel DP through a continuous process.

The light control member LCM may convert a wavelength of a light provided by the display panel DP, for example, a source light or may selectively transmit the source light. Further, the light control member LCM may control optical properties of an external light input from the outside of the display device DD, thereby reducing external light reflectance.

The light control member LCM may include a base layer BL, a color filter layer CFL, and a light control layer CCL. The base layer BL may be arranged to face the base substrate BS of the display panel DP, and the color filter layer CFL and the light control layer CCL arranged on the base layer BL may be positioned between the display panel DP and the base layer BL.

The light control layer CCL may change optical properties of the source light provided from the display panel DP. For example, the light control layer CCL may include a quantum dot that changes a wavelength of the source light provided by the display panel DP. The source light passing through the quantum dot included in the light control layer CCL may be output as a color light having a color different from that of the source light. The light control layer CCL may further include a transmitting part that transmits the source light provided by the display panel DP.

The color filter layer CFL may include color filters having colors (e.g., set or predetermined colors). The color filters may transmit or absorb lights passing through the light control layer CCL according to the colors of the color filters. The color filter layer CFL may absorb a light that is not converted by the light control layer CCL to prevent or reducing degradation of color purity or color reproducibility of the display device DD.

The color filters of the color filter layer CFL may absorb an external light input from the outside of the display device DD depending on the colors of the color filters. The color filters may filter the external light to the same color as a color of a light output by pixels, thereby reducing external light reflectance.

The sealing member SML may be located in the non-display area NDA that is an outer portion of the display module DM and prevent or reduce instances of foreign substances or contaminants such as oxygen, or moisture being introduced into the display module DM from the outside. The sealing member SML may be formed from a sealant including a curable resin.

The display module DM may further include a filler layer FML located between the display panel DP and the light control member LCM. The filler layer FML may fill a space between the display panel DP and the light control member LCM. The filler layer FML may function as a buffer between the display panel DP and the light control member LCM. The filler layer FML may absorb an impact and increase strength of the display module DM.

The filler layer FML may include a polymer resin. For example, the filler layer FML may include an acryl-based resin or an epoxy-based resin. However, according to some embodiments, as the light control member LCM is directly located on the display panel DP, the filler layer FML and the sealing member SML may be omitted. Further, in embodiments in which the light control member LCM is directly located on the display panel DP, the display panel DP provides the base surface, and thus the base layer BL of the light control member LCM may be omitted.

Meanwhile, the display device DD may further include an input sensing module. The input sensing module may acquire coordinate information of the external input applied from the outside of the display device DD. The input sensing module may be driven in various methods such as a capacitive method, a resistive method, an infrared method, or a pressure method, and embodiments according to the present disclosure are not limited to one method.

According to some embodiments, the input sensing module may be located on the display module DM. The input sensing module may be directly located on the display module DM through a continuous process, but embodiments according to the present disclosure are not limited thereto, and the input sensing module may be attached to the display module DM through a separate adhesive layer. Alternatively, the input sensing module may be located between the components of the display module DM. For example, the input sensing module may be located between the display panel DP and the light control member LCM.

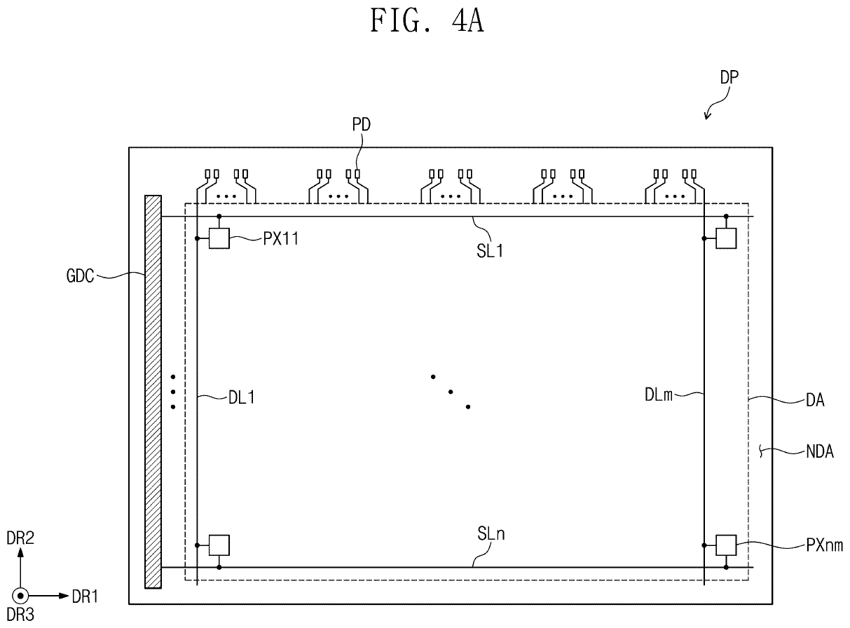

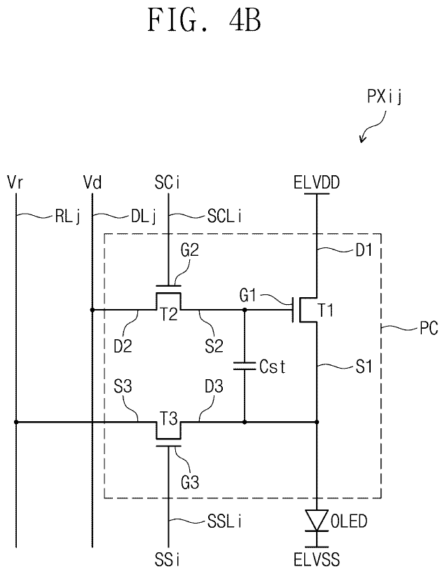

FIG. 4A is a plan view of the display panel DP according to some embodiments of the present disclosure. FIG. 4B is an equivalent circuit diagram of a pixel PXij according to some embodiments of the present disclosure.

Referring to FIG. 4A, the display panel DP may include a display area DA and a non-display area NDA, which may correspond to the display area DA and the non-display area NDA of the display module DM. The display panel DP may include pixels PX11 to PXnm arranged in the display area DA and signal lines SL1 to SLn and DL1 to DLm electrically connected to the pixels PX11 to PXnm and may include a driving circuit GDC and pads PD arranged in the non-display area NDA.

Each of the pixels PX11 to PXnm may include a pixel driving circuit including a light emitting element, transistors (e.g., a switching transistor, a driving transistor, and the like), and a capacitor connected to the light emitting element. The pixels PX11 to PXnm may emit lights in accordance with electrical signals applied to the pixels PX11 to PXnm. FIG. 4A illustratively illustrates the pixels PX11 to PXnm arranged in a matrix form, but an arrangement form of the pixels PX11 to PXnm is not limited thereto.

The signal lines SL1 to SLn and DL1 to DLm may include the scan lines SL1 to SLn and the data lines DL1 to DLm. Each of the pixels PX11 to PXnm may be connected to a corresponding scan line among the scan lines SL1 to SLn and a corresponding data line among the data lines DL1 to DLm. Embodiments according to the present disclosure are not limited thereto, and more types of signal lines may be provided in the display panel DP depending on a configuration of the pixel driving circuit of the pixels PX11 to PXnm.

The driving circuit GDC may include a gate driving circuit. The gate driving circuit may generate gate signals and sequentially output the gate signals to the scan lines SL1 to SLn. The gate driving circuit may further output another control signal to the pixel driving circuits of the pixels PX11 to PXnm. According to some embodiments, the driving circuit GDC and the pixels PX11 to PXnm may include transistors formed through a low temperature polycrystalline silicon (LTPS) process, a low temperature polycrystalline oxide (LTPO) process, or an oxide semiconductor process.

The pads PD may be arranged in one direction on the non-display area NDA. The pads PD may be parts that are connected to a circuit board. The pads PD may be connected to corresponding signal lines among the signal lines SL1 to SLn and DL1 to DLm and may be electrically connected to the pixels PX11 to PXnm through the corresponding signal lines. The pads PD may be arranged on different layers from the signal lines SL1 to SLn and DL1 to DLm and connected through a contact hole, but embodiments according to the present disclosure are not limited thereto, and the pads PD may have an integral shape with the signal lines SL1 to SLn and DL1 to DLm.

FIG. 4B illustratively illustrates a circuit diagram of the one pixel PXij among the pixels PX11 to PXnm. FIG. 4B illustratively illustrates the pixel PXij connected to an i^{th} scan line SCLi, an i^{th} sensing line SSLi, a j^{th} data line DLj, and a j^{th} reference line RLj. Although FIG. 4B illustrates various components in a pixel according to some embodiments, embodiments according to the present disclosure are not limited thereto, and according to various embodiments, the pixel may include additional components or fewer components without departing from the spirit and scope of embodiments according to the present disclosure.

Referring to FIG. 4B, the pixel PXij may include a pixel driving circuit PC and a light emitting element OLED. The pixel driving circuit PC may include transistors T1, T2, and T3 and a capacitor Cst.

The transistors T1, T2, and T3 may be formed through the LTPS process, the LTPO process, or the oxide semiconductor process. Each of the transistors T1, T2, and T3 may include one of a silicon semiconductor and an oxide semiconductor. The oxide semiconductor may include a crystalline or amorphous oxide semiconductor, and the silicon semiconductor may include amorphous silicon or polycrystalline silicon, but embodiments according to the present disclosure are not limited thereto.

Each of the transistors T1, T2, and T3 may be an N-type transistor or a P-type transistor. Hereinafter, each of the transistors T1, T2, and T3 may be described as the N-type transistor, but embodiments according to the present disclosure are not limited thereto, and each of the transistors T1, T2, and T3 may be the P-type transistor or the N-type transistor depending on an applied signal. In this case, a source and a drain of the P-type transistor may correspond to a drain and a source of the N-type transistor.

The transistors T1, T2, and T3 of the pixel driving circuit PC may include the first transistor T1, the second transistor T2, and the third transistor T3. However, the pixel driving circuit PC may further include an additional transistor and an additional capacitor, and embodiments according to the present disclosure are not limited thereto.

The first to third transistors T1, T2, and T3 may include sources S1, S2, and S3, drains D1, D2, and D3, and gates G1, G2, and G3 (or gate electrodes), respectively.

The light emitting element OLED may include a first electrode and a second electrode. According to some embodiments, the first electrode of the light emitting element OLED may be an anode, and the second electrode thereof may be a cathode. The first electrode of the light emitting element OLED may receive a first voltage ELVDD through the first transistor T1, and a second electrode of the light emitting element OLED may receive a second voltage ELVSS. The light emitting element OLED may emit a light by receiving the first voltage ELVDD and the second voltage ELVSS.

The first transistor T1 may be electrically connected between the light emitting element OLED and a voltage line that receives the first voltage ELVDD. The first transistor T1 may include the first drain D1 that receives the first voltage ELVDD, the first source S1 connected to the first electrode of the light emitting element OLED, and the first gate G1 connected to the capacitor Cst. The first transistor T1 may control a driving current flowing through the light emitting element OLED from the first voltage ELVDD in response to a voltage value stored in the capacitor Cst. The first transistor T1 may be defined as a driving transistor.

The second transistor T2 may be electrically connected between the jth data line DLj and the capacitor Cst. The second transistor T2 may include the second drain D2 connected to the jth data line DLj, the second source S2 connected to the capacitor Cst, and the second gate G2 connected to the i^{th} scan line SCLi that receives an i^{th} write scan signal SCi. The second transistor T2 may provide a data voltage Vd to the first transistor T1 in response to the i^{th} write scan signal SCi. The second transistor T2 may be defined as a switching transistor.

The third transistor T3 may be electrically connected between the jth reference line RLj and the light emitting element OLED. The third transistor T3 may include the third source S3 connected to the jth reference line RLj, the third drain D3 connected to the first electrode of the light emitting element OLED, and the third gate G3 connected to the i^{th} sensing line SSLi that receives an i^{th} sampling scan signal SSi. The j^{th} reference line RLj may receive a reference voltage Vr.

The capacitor Cst may store various voltage difference values according to an input signal. For example, the capacitor Cst may store a voltage corresponding to a difference between a voltage received from the second transistor T2 and the first voltage ELVDD.

Meanwhile, the equivalent circuit of the pixel PXij in the present disclosure is not limited to the equivalent circuit illustrated in FIG. 4B. According to some embodiments of the present disclosure, the pixel PXij may be implemented in various forms to allow the light emitting element OLED to emit a light.

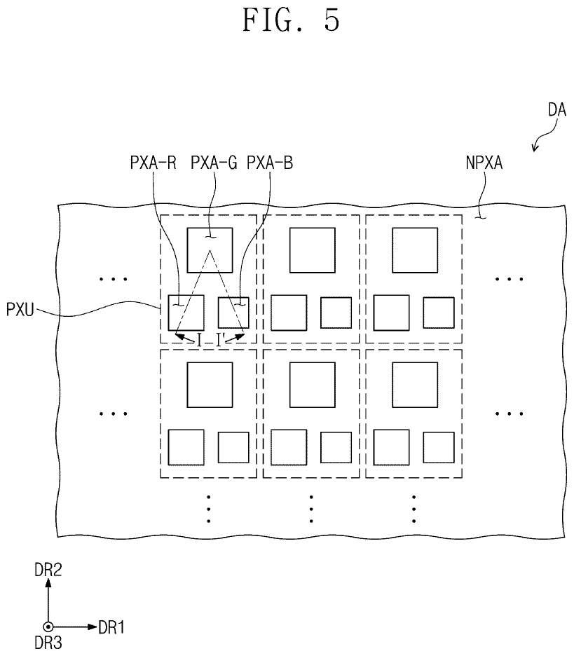

FIG. 5 is an enlarged plan view of the display area DA according to some embodiments of the present disclosure.

As illustrated in FIG. 5, unit pixels PXU may be arranged in the first direction DR1 and the second direction DR2. According to some embodiments, the unit pixel PXU may include a first pixel, a second pixel, and a third pixel that emit lights having different colors. The first pixel, the second pixel, and the third pixel may output a red light, a green light, and a blue light, respectively. FIG. 4 illustrates a first pixel area PXA-R, a second pixel area PXA-G, and a third pixel area PXA-B representing the first pixel, the second pixel, and the third pixel, respectively. The first pixel area PXA-R may be an area in which a light generated by the first pixel is provided to the outside, the second pixel area PXA-G may be an area in which a light generated by the second pixel is provided to the outside, and the third pixel area PXA-B may be an area in which a light generated by the third pixel is provided to the outside.

A peripheral area NPXA may be arranged to surround the first pixel area PXA-R, the second pixel area PXA-G, and the third pixel area PXA-B. Further, the peripheral area NPXA may be located between the first pixel area PXA-R, the second pixel area PXA-G, and the third pixel area PXA-B. The peripheral area NPXA may set the boundaries of the first pixel area PXA-R, the second pixel area PXA-G, and the third pixel area PXA-B and may prevent or reduce color mixing between the first pixel area PXA-R, the second pixel area PXA-G, and the third pixel area PXA-B.

Referring to FIG. 5, the first pixel area PXA-R and the third pixel area PXA-B may be arranged in the same row, and the second pixel area PXA-G may be arranged in a different row from the first pixel area PXA-R and the third pixel area PXA-B. The second pixel area PXA-G may have the largest area, and the third pixel area PXA-B may have the smallest area, but embodiments according to the present disclosure are not limited thereto. According to some embodiments, it is illustrated that the first pixel area PXA-R, the second pixel area PXA-G, and the third pixel area PXA-B have square (or substantially square) shapes, but this is illustrative, and embodiments according to the present disclosure are not limited thereto.

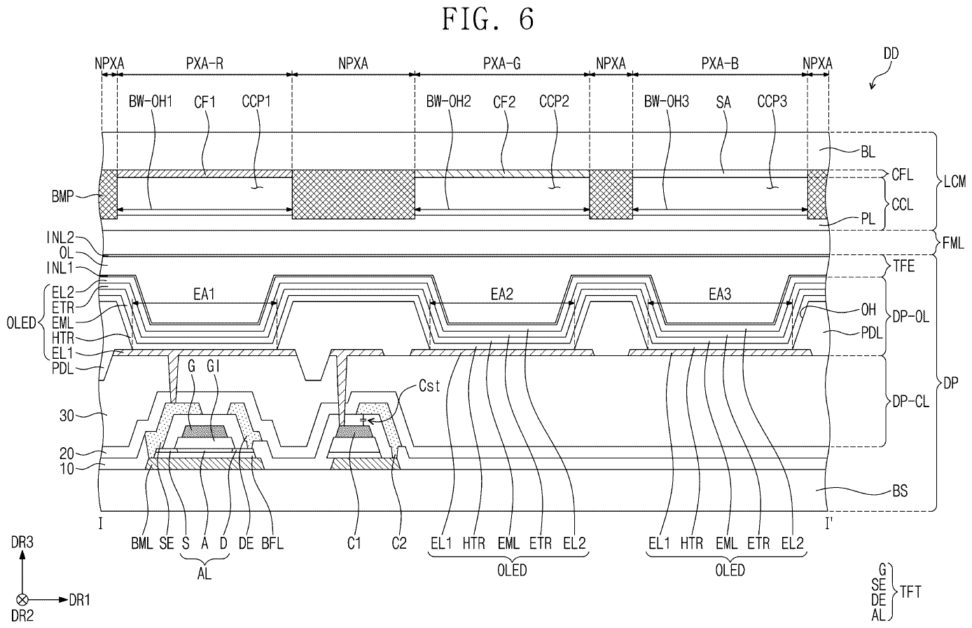

FIG. 6 is a cross-sectional view of a portion of the display device DD according to some embodiments of the present disclosure.

FIG. 6 illustrates a cross section corresponding to cut line I-I′ of FIG. 5, this is illustrative, and embodiments according to the present disclosure are not limited thereto. FIG. 6 illustratively illustrates a cross section of the first to third pixel areas PXA-R, PXA-G, and PXA-B and the peripheral area NPXA. In description of FIG. 6, description is made with reference to FIG. 3, and descriptions of the same reference numerals will be omitted.

Referring to FIG. 6, the display panel DP may include the base substrate BS, the circuit layer DP-CL, the display element layer DP-OL, and the encapsulation layer TFE.

The circuit layer DP-CL may include a conductive pattern BML, a buffer pattern BFL, a transistor TFT, first to third insulating layers 10, 20, and 30, and a gate insulating layer GI.

The conductive pattern BML may be located on the base substrate BS. The conductive pattern BML may include one of molybdenum (Mo), aluminum (Al), chromium (Cr), gold (Au), titanium (Ti), nickel (Ni), neodymium (Nd), and copper (Cu), or an alloy thereof. FIG. 6 illustrates the conductive pattern BML as one layer, but embodiments according to the present disclosure are not limited thereto. For example, the conductive pattern BML may have a single-layer structure including one pattern layer or may include more pattern layers.

The buffer pattern BFL may be located on the conductive pattern BML. The buffer pattern BFL may relatively improve a coupling force between the base substrate BS and the semiconductor pattern. The buffer pattern BFL may include at least one inorganic film. For example, the buffer pattern BFL may include a silicon oxide layer and a silicon nitride layer. The silicon oxide layer and the silicon nitride layer may be alternately laminated.

The transistor TFT may be located on the buffer pattern BFL. The transistor TFT may include a semiconductor pattern AL, a source electrode SE, a drain electrode DE, and a gate electrode “G.”

The semiconductor pattern AL may be located on the buffer pattern BFL. The semiconductor pattern AL may overlap the buffer pattern BFL on a plane (e.g., in a plan view). The semiconductor pattern AL may include polysilicon. However, embodiments according to the present disclosure are not limited thereto, and the semiconductor pattern AL may include amorphous silicon or a metal oxide. FIG. 6 merely illustratively illustrates a portion of the semiconductor pattern AL, and the semiconductor pattern may be further located in the plurality of pixel areas PXA-R, PXA-G, and PXA-B (see FIG. 5). The semiconductor pattern may be arranged in a specific rule across the plurality of pixel areas PXA-R, PXA-G, and PXA-B. The semiconductor pattern AL may have different electrical properties depending on whether the semiconductor pattern AL is doped.

The semiconductor pattern AL may include a source area “S,” a drain area “D,” and a channel area “A.” The source area “S” and the drain area “D” may extend in opposite directions with the channel area “A” interposed therebetween. That is, the drain area “D” may be spaced apart from the source area “S,” and the channel area “A” may be formed between the source area “S” and the drain area “D.”

The semiconductor pattern AL may include a first area having high conductivity and a second area having low conductivity. The first area may be doped with an N-type dopant or a P-type dopant. A P-type transistor may include a doped area doped with the P-type dopant, and an N-type transistor may include a doped area doped with the N-type dopant. The second area may be a non-doped area or may be an area doped at a concentration that is lower than a concentration of the first area.

The conductivity of the first area is greater than the conductivity of the second area. The first area may serve as an electrode or a signal line. The second area may correspond (or substantially correspond) to the channel area “A” of the transistor. In other words, a portion of the semiconductor pattern AL may be the channel area “A” of the transistor, another portion thereof may be the source area “S” or the drain area “D,” and still another portion thereof may be a connection electrode or a connection signal line.

The gate insulating layer GI may be located on the semiconductor pattern AL. The gate insulating layer GI may be arranged to overlap the channel area “A” of the semiconductor pattern AL and may cover a portion of the semiconductor pattern AL.

The gate electrode “G” may be arranged to overlap the gate insulating layer GI. The first insulating layer 10 may be located on the base substrate BS to cover the semiconductor pattern AL and the gate electrode “G.” A hole through which portions of the source area “S” and the drain area “D” of the semiconductor pattern AL are exposed may be defined in the first insulating layer 10.

The source electrode SE and the drain electrode DE may be formed on the first insulating layer 10 and may be in contact with the source area “S” and the drain area “D” through the hole. For example, the source electrode SE may be in contact with the source area “S” of the semiconductor pattern AL, and the drain electrode DE may be in contact with the drain area “D” of the semiconductor pattern AL.

The second insulating layer 20 may be located on the first insulating layer 10 to cover the source electrode SE and the drain electrode DE. The first insulating layer 10 and the second insulating layer 20 may be inorganic layers. The third insulating layer 30 may be located on the second insulating layer 20 to cover the second insulating layer 20. The third insulating layer 30 may be an organic layer. A first electrode EL1 may be connected to the source electrode SE through a contact hole defined through the second insulating layer 20 and the third insulating layer 30. Thus, the first electrode EL1 may be electrically connected to a corresponding circuit element through a contact hole defined through the second insulating layer 20 and the third insulating layer 30.

The circuit layer DP-CL may further include a first conductive pattern C1 including the same material as the gate electrode “G” and formed through the same process as the gate electrode “G” and a second conductive pattern C2 including the same material as the source electrode SE and the drain electrode DE and formed through the same process as the source electrode SE and the drain electrode DE. The first conductive pattern C1 and the second conductive pattern C2 may form the capacitor Cst.

The display element layer DP-OL may include the light emitting element OLED and a pixel defining film PDL.

The light emitting element OLED may include the first electrode EL1, a second electrode EL2 facing the first electrode EL1, and a light emitting layer EML located between the first electrode EL1 and the second electrode EL2. The light emitting layer EML included in the light emitting element OLED may include an organic light emitting material or a quantum dot as a light emitting material. The light emitting element OLED may further include a hole transport area HTR and/or an electron transport area ETR. Meanwhile, according to some embodiments, the light emitting element OLED may further include a capping layer located on the second electrode EL2.

The pixel defining film PDL may be located on the circuit layer DP-CL and cover a portion of the first electrode EL1. A light emitting opening OH may be defined in the pixel defining film PDL. At least a portion of the first electrode EL1 is exposed through the light emitting opening OH of the pixel defining film PDL. A first light emitting area EA1, a second light emitting area EA2, and a third light emitting area EA3 may be defined to correspond to a portion of the first electrode EL1, which is exposed by the light emitting opening OH of the pixel defining film PDL. The first light emitting area EA1, the second light emitting area EA2, and the third light emitting area EA3 may correspond to the first pixel area PXA-R, the second pixel area PXA-G, and the third pixel area PXA-B, respectively. An area except for the first light emitting area EA1, the second light emitting area EA2, and the third light emitting area EA3 may be defined as a non-light emitting area.

Meanwhile, in the specification, the wording “corresponding” means that two components overlap each other when viewed in the thickness direction DR3 of the display device DD (or when viewed on a plane (e.g., in a plan view)) and is not limited to the same area. The first light emitting area EA1, the second light emitting area EA2, and the third light emitting area EA3 may overlap the first pixel area PXA-R, the second pixel area PXA-G, and the third pixel area PXA-B, respectively. When viewed on a plane (e.g., in a plan view), areas of the first pixel area PXA-R, the second pixel area PXA-G, and the third pixel area PXA-B may be larger than areas of the first light emitting area EA1, the second light emitting area EA2, and the third light emitting area EA3, which are distinguished by the pixel defining film PDL. However, this is merely illustrative, and embodiments according to the present disclosure are not limited thereto. The areas of the pixel areas PXA-R, PXA-G, and PXA-B may be the same (or substantially the same) as the areas of the light emitting areas EA1, EA2, and E3, which are distinguished by the pixel defining film PDL.

The first electrode EL1 may be located on the circuit layer DP-CL. The first electrode EL1 may be an anode or a cathode. Further, the first electrode EL1 may be a pixel electrode. The first electrode EL1 may be a transmissive electrode, a semi-transmissive electrode, or a reflective electrode.

The hole transport area HTR may be located on the first electrode EL1. The hole transport area HTR may be commonly arranged in the first light emitting area EA1, the second light emitting area EA2, the third light emitting area EA3, and the non-light emitting area. A common layer such as the hole transport area HTR may be arranged to overlap the plurality of unit pixels PXU in the display area DA illustrated in FIG. 5. However, embodiments according to the present disclosure are not limited thereto, and the hole transport area HTR may be separately arranged to correspond to each of the first light emitting area EA1, the second light emitting area EA2, and the third light emitting area EA3. The hole transport area HTR may include at least one of a hole transport layer, a hole injection layer, or an electron blocking layer.

The light emitting layer EML may be located on the hole transport area HTR. The light emitting layer EML may be commonly arranged in the first light emitting area EA1, the second light emitting area EA2, the third light emitting area EA3, and the non-light emitting area. The light emitting layer EML may be arranged to overlap the entire hole transport area HTR and the entire electron transport area ETR. However, embodiments according to the present disclosure are not limited thereto, and according to some embodiments, the light emitting layer EML may be located inside the light emitting opening OH. That is, the light emitting layer EML may be separately arranged to correspond to the first light emitting area EA1, the second light emitting area EA2, and the third light emitting area EA3, which are distinguished by the pixel defining film PDL.

The light emitting layer EML may generate a source light. According to some embodiments, the light emitting layer EML may emit a blue light. In the display device DD according to some embodiments, a blue light may be a source light. Meanwhile, when the light emitting layer EML is separately arranged to correspond to the first light emitting area EA1, the second light emitting area EA2, and the third light emitting area EA3, the light emitting layer EML may emit a blue light or may emit lights having different wavelength ranges from the first light emitting area EA1, the second light emitting area EA2, and the third light emitting area EA3.

The light emitting layer EML may have a multi-layer structure having a single layer made of a single material, a single layer made of a plurality of different materials, or a plurality of layers made of a plurality of different materials. The light emitting layer EML may include a fluorescent or phosphorescent material. In the light emitting element OLED according to some embodiments, the light emitting layer EML may include a light emitting material such as an organic light emitting material, a metal organic complex, or a quantum dot.

The light emitting layer EML may have a multi-layer structure unlike the illustration of FIG. 6. For example, the light emitting layer EML may include a first light emitting layer, a charge generating layer, and a second light emitting layer that emits a light having a different color from that of the first light emitting layer, the first light emitting layer, the charge generating layer, and the second light emitting layer being sequentially laminated in the third direction DR3. The first light emitting layer may emit, for example, a blue light, and the second light emitting layer may emit, for example, a green light. The charge generating layer may be located between the first light emitting layer and the second light emitting layer, supply an electron or a hole to each of the first light emitting layer and the second light emitting layer, and thus relatively improve light emitting efficiency.

The electron transport area ETR may be located on the light emitting layer EML. The electron transport area ETR may include at least one of an electron injection layer, an electron transport layer, or a hole blocking layer. The electron transport area ETR may be arranged as a common layer to overlap the entireties of the first light emitting area EA1, the second light emitting area EA2, and the third light emitting area EA3 and the pixel defining film PDL. However, embodiments according to the present disclosure are not limited thereto, and the electron transport area ETR may be separately arranged to correspond to the first light emitting area EA1, the second light emitting area EA2, and the third light emitting area EA3.

The second electrode EL2 may be located on the electron transport area ETR. The second electrode EL2 may be a common electrode. The second electrode EL2 may be a cathode or an anode, but embodiments according to the present disclosure are not limited thereto. For example, when the first electrode EL1 is the anode, the second electrode EL2 may be the cathode, or when the first electrode EL1 is the cathode, the second electrode EL2 may be the anode. The second electrode EL2 may be a transmissive electrode, a semi-transmissive electrode, or a reflective electrode.

The encapsulation layer TFE may be located on the second electrode EL2. Alternatively, when the light emitting element OLED includes the capping layer, the encapsulation layer TFE may be located on the capping layer. The encapsulation layer TFE may protect the display element layer DP-OL from moisture and oxygen and prevent or reduce inflow of foreign substances or contaminants such as dust.

The encapsulation layer TFE may include at least one inorganic film INL1 or INL2. The inorganic films INL1 and INL2 may include at least one of a silicon nitride, a silicon oxynitride, a silicon oxide, a titanium oxide, or an aluminum oxide. The encapsulation layer TFE may include at least one organic film OL. The organic film OL may include an organic polymer material formed from an acrylate-based resin. However, this is illustrative, and embodiments according to the present disclosure are not limited thereto.

The light control member LCM may be located on the display panel DP. The light control member LCM may include the base layer BL, a division pattern BMP, the color filter layer CFL, and the light control layer CCL. The division pattern BMP may be located under the base layer BL.

The base layer BL may be a member that provides a base surface on which the color filter layer CFL or the like is located. The base layer BL may include a glass or a synthetic resin layer. The synthetic resin layer may include a thermosetting resin. In particular, the synthetic resin layer may be a polyimide-based resin layer, and a material thereof is not particularly limited thereto. The synthetic resin layer may include at least one of an acrylic resin, a methacrylic resin, a polyisoprene, a vinyl resin, an epoxy resin, a urethane resin, a cellulose resin, a siloxane resin, a polyamide resin, or a perylene resin. In addition, the base layer BL may include a glass substrate, a metal substrate, an organic/inorganic composite material substrate, or the like.

The division pattern BMP may be located under the base layer BL. The division pattern BMP may be arranged to correspond to the peripheral area NPXA located between the pixel areas PXA-R, PXA-G, and PXA-B. The division pattern BMP may define boundaries between the adjacent pixel areas PXA-R, PXA-G, and PXA-B. A first color filter CF1, a second color filter CF2, and a selective absorption layer SA, which will be described below, may be arranged to be spaced apart from each other by the division pattern BMP. The first color filter CF1, the second color filter CF2, and the selective absorption layer SA may be arranged inside openings BW-OH1, BW-OH2, and BW-OH3 defined in the division pattern BMP. Further, a first light control unit CCP1, a second light control unit CCP2, and a third light control unit CCP3, which will be described below, may be arranged to be spaced apart from each other by the division pattern BMP. The first light control unit CCP1, the second light control unit CCP2, and the third light control unit CCP3 may be arranged inside the openings BW-OH1, BW-OH2, and BW-OH3 defined in the division pattern BMP.

The division pattern BMP may include a material having transmittance that is smaller than or equal to a value (e.g., a set or predetermined value). For example, the division pattern BMP may include a light shielding material and may include a black coloring agent. The division pattern BMP may include a black dye or a black pigment mixed with a base resin. The division pattern BMP, for example, the black coloring agent, may include carbon black or include a metal such as chromium or an oxide thereof. The division pattern BMP may include, for example, at least one of propylene glycol methyl ether acetate, 3-methoxy-n-butyl acetate, an acrylate monomer, an acrylic monomer, an organic pigment, or an acrylate ester.

The color filter layer CFL may be located under the base layer BL. The color filter layer CFL may include the color filters CF1 and CF2 and the selective absorption layer SA. The color filter layer CFL may include the first color filter CF1 that transmits a second color light to the first pixel area PXA-R and may include the second color filter CF2 that transmits a third color light to the second pixel area PXA-G. For example, the first color filter CF1 may be a red color filter, and the second color filter CF2 may be a green color filter. Meanwhile, the first color filter CF1 and the second color filter CF2 may be yellow color filters. The first color filter CF1 and the second color filter CF2 may be integrally provided without being separated from each other. The color filter layer CFL may include the selective absorption layer SA in the third pixel area PXA-B. A detailed content related to the selective absorption layer SA will be described below.

The first color filter CF1 may increase color purity by transmitting only a portion of a wavelength range of the second color light, that is, a light in a center wavelength range. The second color filter CF2 may increase color purity by transmitting only a portion of a wavelength range of the third color light, that is, a light in a center wavelength range. The selective absorption layer SA may transmit a light provided from the light control layer CCL.

Each of the first color filter CF1 and the second color filter CF2 may include color filter particles. The color filter particles may include pigments or dyes. The first color filter CF1 may include a red pigment or a red dye, and the second color filter CF2 may include a green pigment or a green dye. The color filter particles may be used alone or in combination of two or more types.

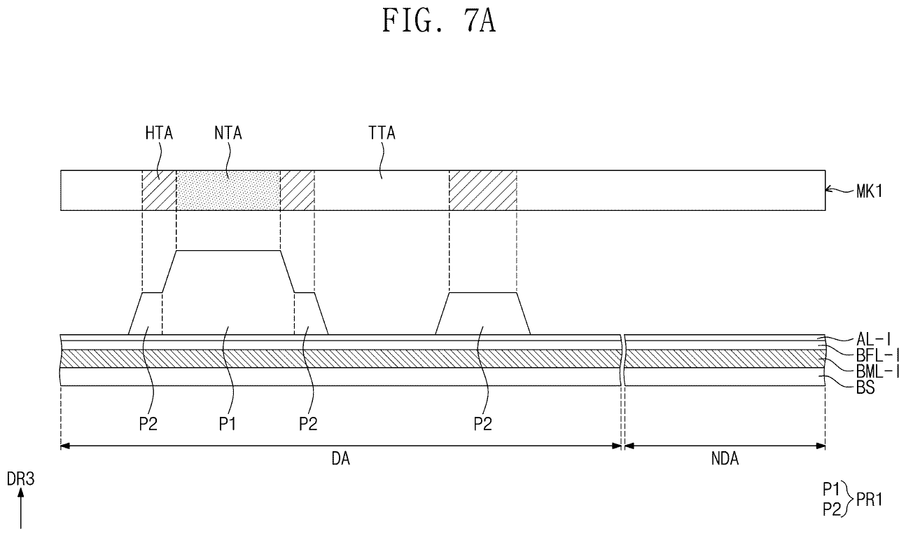

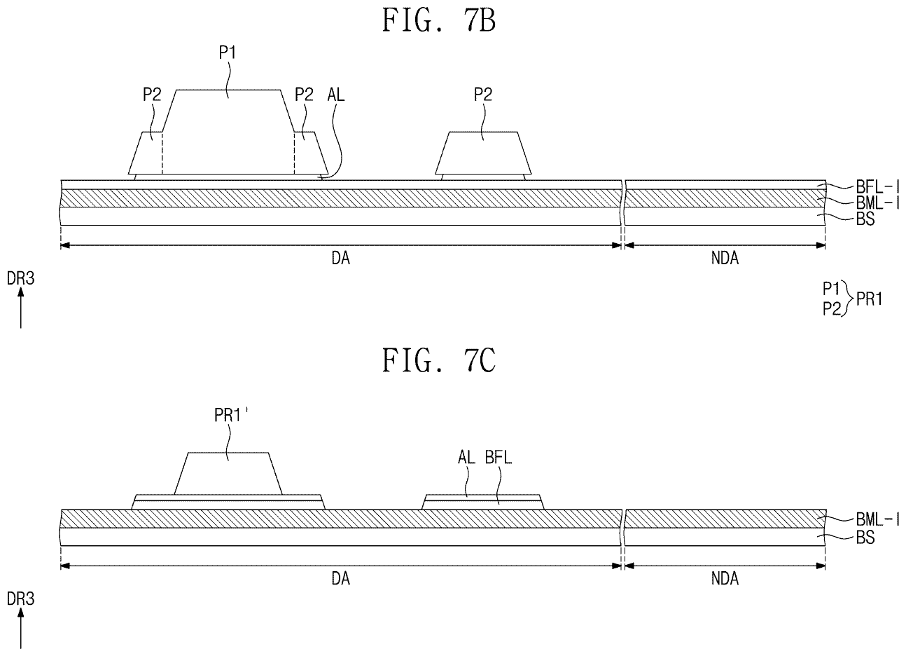

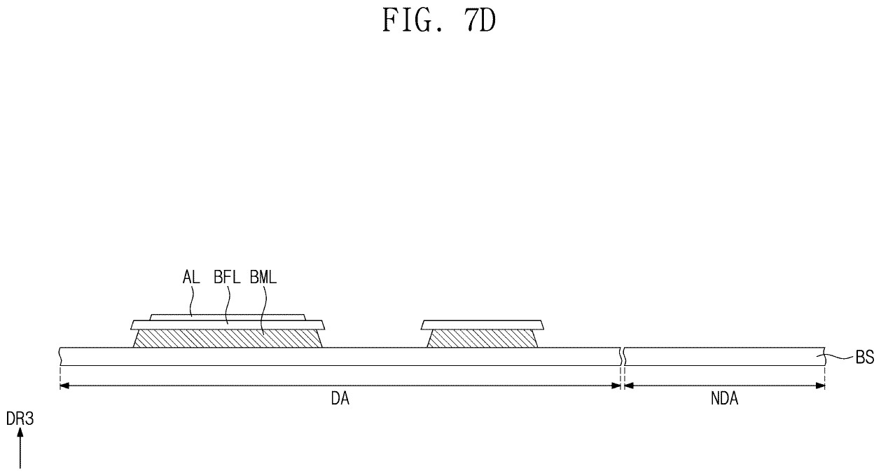

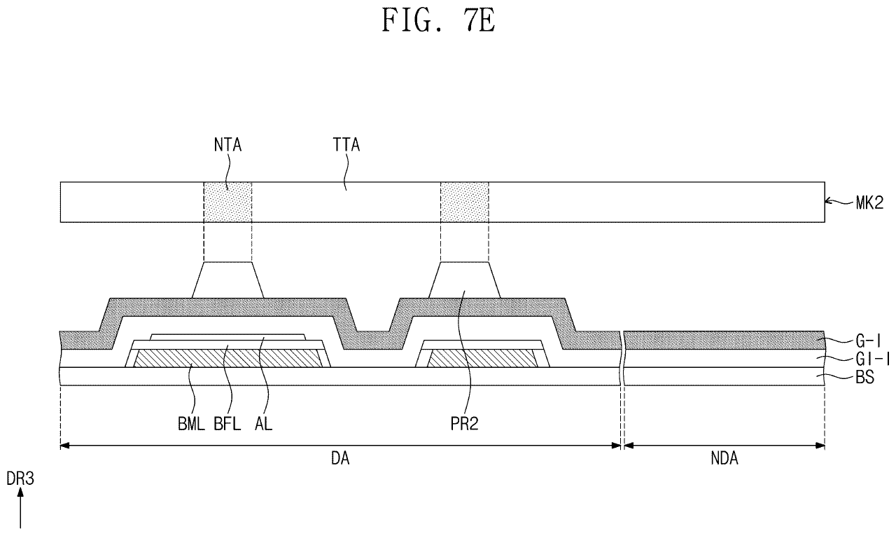

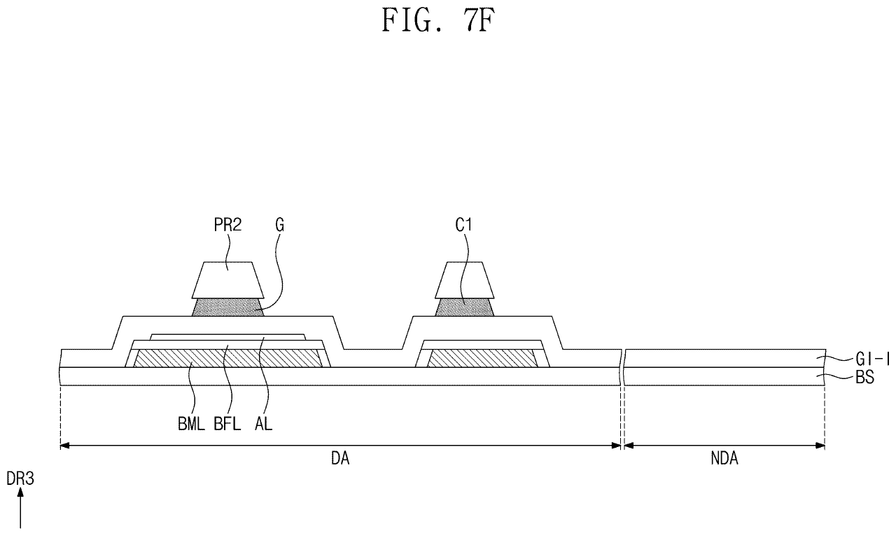

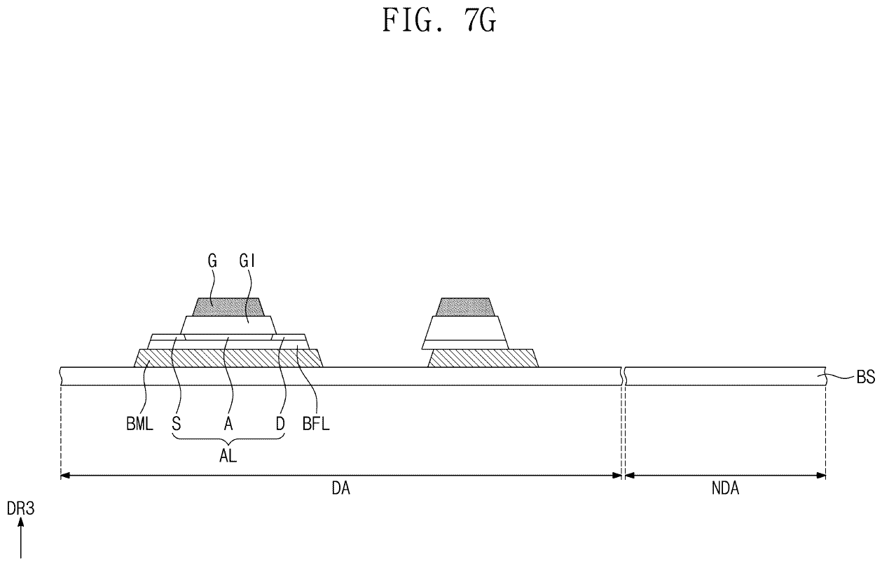

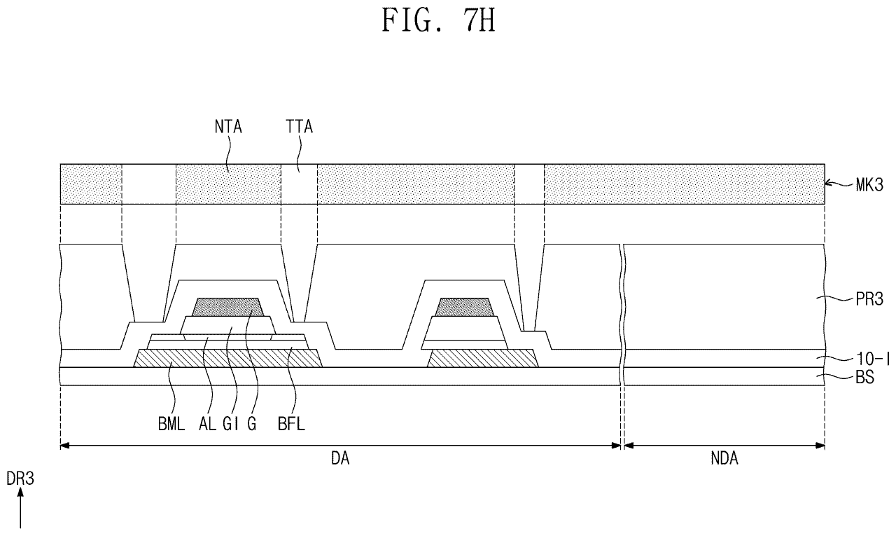

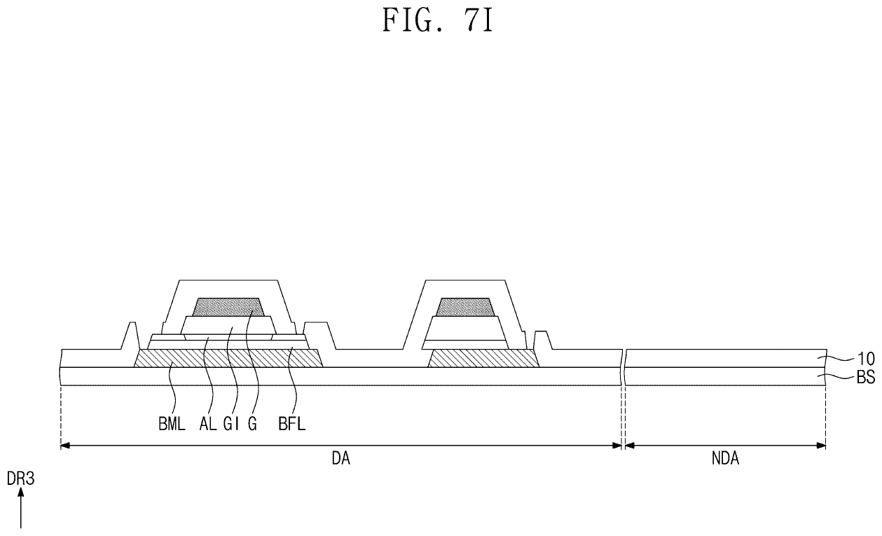

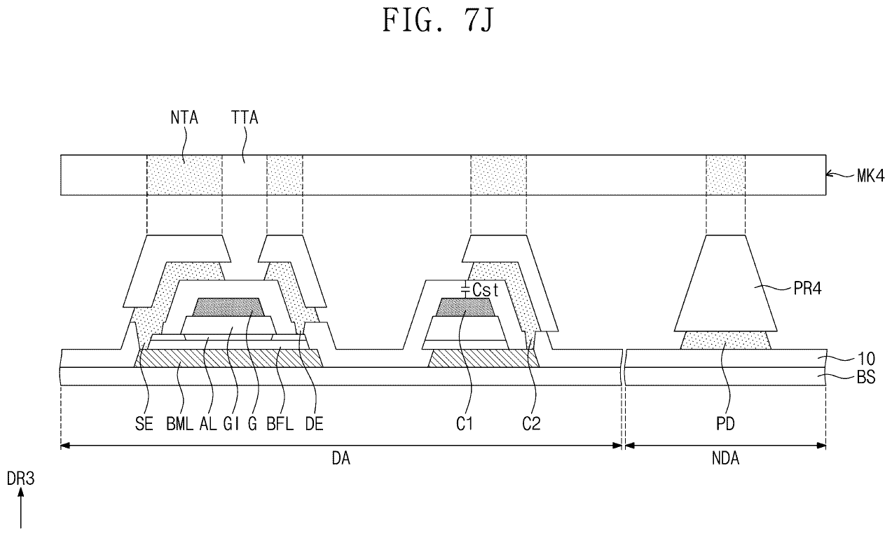

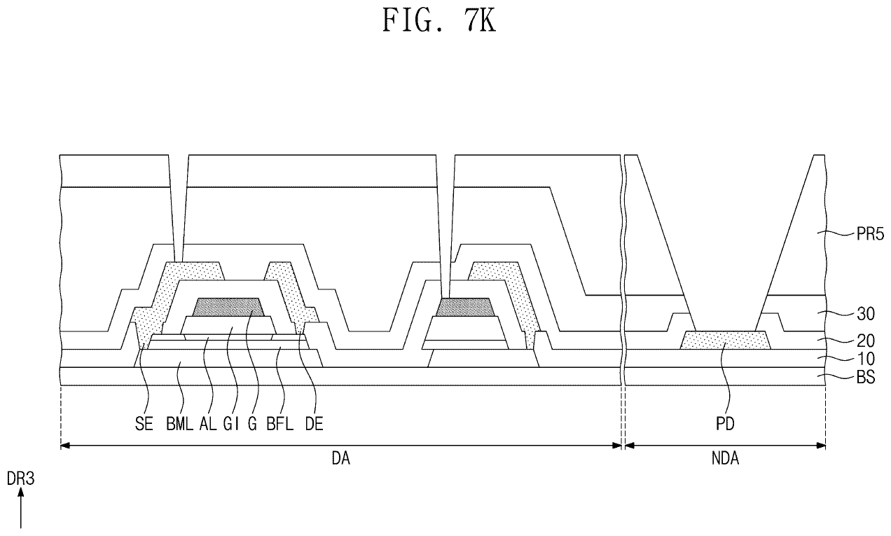

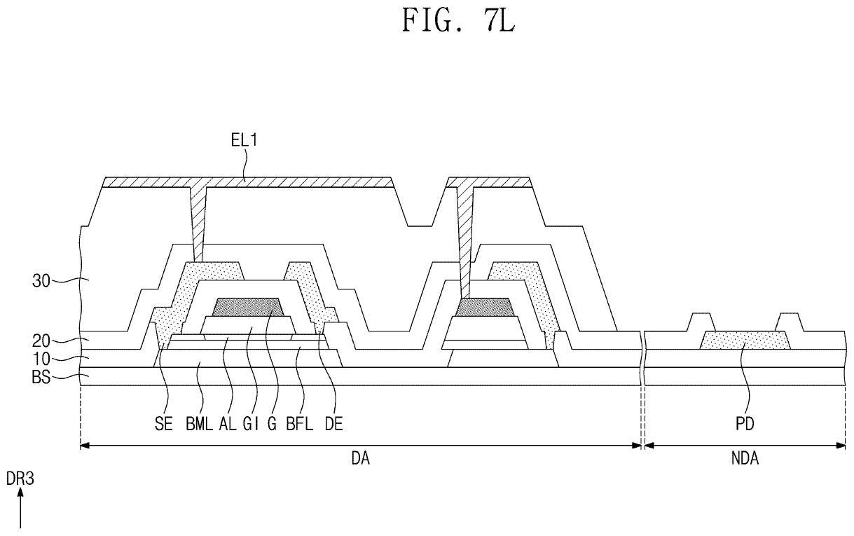

As dyes, color index (C.I.) solvent red 1, 2, 3, 4, 8, 16, 17, 18, 19, 23, 24, 25, 26, 27, 30, 33, 35, 41, 43, 45, 48, 49, 52, 68, 69, 72, 73, 83:1, 84:1, 89, 90, 90:1, 91, 92, 106, 109, 110, 118, 119, 122, 124, 125, 127, 130, 132, 135, 141, 143, 145, 146, 149, 150, 151, 155, 160, 161, 164, 164:1, 165, 166, 168, 169, 172, 175, 179, 180, 181, 182, 195, 196, 197, 198, 207, 208, 210, 212, 214, 215, 218, 222, 223, 225, 227, 229, 230, 233, 234, 235, 236, 238, 239, 240, 241, 242, 243, 244, 245, 247, 248, solvent blue 2, 3, 4, 5, 7, 18, 25, 26, 35, 36, 37, 38, 43, 44, 45, 48, 51, 58, 59, 59:1, 63, 64, 67, 68, 69, 70, 78, 79, 83, 94, 97, 98, 100, 101, 102, 104, 105, 111, 112, 122, 124, 128, 129, 132, 136, 137, 138, 139, 143, solvent green 1, 3, 4, 5, 7, 28, 29, 32, 33, 34, 35, acid red 6, 11, 26, 51, 52, 60, 87, 88, 92, 94, 111, 186, 215, 289, 388, acid green 25, 27, acid blue 22, 25, 40, 78, 92, 113, 129, 167, 230, acid yellow 17, 23, 25, 36, 38, 42, 44, 72, 78, acid violet 9, 30, basic red 1, 2, 13, 14, 22, 27, 29, 39, basic green 3, 4, basic blue 3, 9, 41, 66, basic violet 1, 3, 18, 39, 66, basic yellow 11, 23, 25, 28, 41, direct red 4, 23, 31, 75, 76, 79, 80, 81, 83, 84, 149, 224, direct green 26, 28, direct Blue 71, 78, 98, 106, 108, 192, 201, direct violet 51, direct yellow 26, 27, 28, 33, 44, 50, 86, 142 or the like may be used, and embodiments according to the present disclosure are not limited thereto. A cationic dye may be used as the dye so that the dye may be selectively well adsorbed to the selective absorption layer SA (see FIG. 7A). For example, an azo-based dye, a triarylmethane-based dye, an anthraquinone-based dye, or a heterocyclic-based dye may be used as the dye.

As pigments, color index (C. I.) red 5, 9, 81, 83, 88, 112, 144, 149, 168, 170, 176, 177, 188, 207, 209, 254, 255, 264, yellow 3, 40, 73, 74, 83, 97,128, 138, 139, 154, 223, green 7, 17, 26, 36, blue 15:6, 27, 28, 29, 33, 60, Violet 14, 19, 23, 37, 42 or the like may be used, and embodiments according to the present disclosure are not limited thereto.

When the pigments are used, surface treatment may be performed using a dispersant to ensure dispersion stability. In this case, a cationic dispersant may be used as the dispersant so that the dispersant may be selectively well adsorbed to the selective absorption layer SA (see FIG. 7A). For example, polyDADMAC (polydimethyldiallylammonium chloride), polyamine (e.g., polyethyleneimine), or polyquaternium (e.g., polyquaternium-10) may be used as the cationic dispersant.

Further, each of the first color filter CF1 and the second color filter CF2 may include a small amount of color conversion particles. Each the first color filter CF1, the second color filter CF2, and the selective absorption layer SA may include a metal hydrate particle and a binder resin having a negative surface zeta potential.

The first color filter CF1, the second color filter CF2, and the selective absorption layer SA may be arranged to correspond to the first pixel area PXA-R, the second pixel area PXA-G, and the third pixel area PXA-B, respectively. Further, the first color filter CF1, the second color filter CF2, and the selective absorption layer SA may be arranged to correspond to the first light control unit CCP1, the second light control unit CCP2, and the third light control unit CCP3, respectively.

The light control layer CCL may be located under the color filter layer CFL. The light control layer CCL may include the first light control unit CCP1, the second light control unit CCP2, and the third light control unit CCP3 and a planarization layer PL. On a plane (e.g., in a plan view), the first light control unit CCP1, the second light control unit CCP2, and the third light control unit CCP3 may overlap the first pixel area PXA-R, the second pixel area PXA-G, and the third pixel area PXA-B, respectively. The first light control unit CCP1, the second light control unit CCP2, and the third light control unit CCP3 may be arranged to be spaced apart from each other. The first light control unit CCP1, the second light control unit CCP2, and the third light control unit CCP3 may be arranged to be spaced apart from each other by the division pattern BMP. The first light control unit CCP1, the second light control unit CCP2, and the third light control unit CCP3 may be arranged inside the openings BW-OH1, BW-OH2, and BW-OH3 defined in the division pattern BMP.

The light control units CCP1, CCP2, and CCP3 may be units that convert the wavelength of the source light provided from the display element layer DP-OL or transmit the provided source light without converting the wavelength thereof.

The light control layer CCL may include color converting particles, and the color converting particles may include quantum dots or phosphors.

The light control layer CCL may include the first light control unit CCP1 including a first quantum dot or a first phosphor that converts a first color light provided from the light emitting element OLED into a second color light, the second light control unit CCP2 including a second quantum dot or a second phosphor that converts the first color light into a third color light, and the third light control unit CCP3 that transmits the first color light. The first light control unit CCP1 may provide a red light that is the second color light, and the second light control unit CCP2 may provide a green light that is the third color light. The third light control unit CCP3 may transmit and provide a blue light that is the first color light provided from the light emitting element OLED. For example, the first quantum dot and the first phosphor may be a red quantum dot, and the second quantum dot and the second phosphor may be a green quantum dot.

The light control layer CCL may include a small amount of color filter particles. For example, the first light control unit CCP1 and the second light control unit CCP2 may include a small amount of color filter particles. The third light control unit CCP3 may not include the color filter particles.

The quantum dot means crystals of semiconductor compounds. As a size of the quantum dot is adjusted or an element ratio inside the quantum dot is adjusted, an energy band gap may be adjusted, and thus lights having various wavelengths may be obtained. For example, a diameter of the quantum dot may be in a range of 1 nm to 10 nm (or about 1 nm to 10 nm). Thus, as quantum dots having different sizes are used or quantum dots having different element ratios inside the quantum dots are used, the light emitting element OLED that emits lights having various wavelengths may be implemented. For example, the quantum dot may be implemented to emit a red light, a green light, or a blue light. Further, the quantum dot may be configured to couple lights having various colors to emit a white light.

The quantum dot may be synthesized by a wet chemical process, an organic metal chemical vapor deposition process, a molecular beam epitaxy process, or a process similar thereto. The wet chemical process is a method of growing quantum dot particle crystals after mixing an organic solvent and a precursor material. When the crystals are grown, the organic solvent may serve as a dispersant that is naturally coordinated to a quantum dot crystal surface and adjust the growth of the crystals. Thus, the wet chemical process may be easier than a vapor deposition method such as metal organic chemical vapor deposition (MOCVD) or molecular beam epitaxy (MBE) and may control growth of quantum dot particles through a low-cost process.

The quantum dot may have a single structure in which concentrations of elements included in the quantum dot are uniform or a core-shell dual structure. For example, a material included in a core and a material included in a shell may be different from each other. The shell of the quantum dot may serve as a protective layer for maintaining semiconductor characteristics by preventing or reducing chemical modification of the core and/or a charging layer for providing electrophoretic characteristics to the quantum dot. The shell may be a single layer or a multi-layer. The core/shell structure may have a concentration gradient in which the concentration of the element that is present in the shell decreases toward the core.

The core of the quantum dot may be selected from a group II-VI compound, a group III-VI compound, a group I-III-VI compound, a group III-V compound, a group III-II-V compound, a group IV-VI compound, a group IV element, a group IV compound, and a combination thereof.

The group II-VI compound may be selected from the group consisting of a binary compound selected from the group consisting of CdSe, CdTe, CdS, ZnS, ZnSe, ZnTe, ZnO, HgS, HgSe, HgTe, MgSe, and MgS and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, and HgZnSeTe and a mixture thereof.

The group III-VI compound may include a binary compound such as In₂S₃ and In₂Se₃, a ternary compound such as InGaS₃ and InGaSe₃, or any combination thereof.

The group I-III-VI compound may be selected from a ternary compound selected from the group consisting of AgInS, AgInS₂, CuInS, CuInS₂, AgGaS₂, CuGaS₂, CuGaO₂, AgGaO₂, and AgAlO₂, and a mixture thereof or a quaternary compound such as AgInGaS₂ and CuInGaS₂.

The group III-V compound may be selected from the group consisting of a binary compound selected from the group consisting of GaN, GaP, GaAs, GaSb, AlN, AlP, AlAs, AlSb, InN, InP, InAs, and InSb and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, and InPSb and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb and a mixture thereof. Meanwhile, the group III-V compound may further include a group II metal. For example, InZnP or the like may be selected as the group III-II-V compound.

The IV-VI compound may be selected from the group consisting of a binary compound selected from the group consisting of SnS, SnSe, SnTe, PbS, PbSe, and PbTe and a mixture thereof, a ternary compound selected from the group consisting of SnSeS, SnSeTe, SnSTe, PbSeS, PbSeTe, PbSTe, SnPbS, SnPbSe, and SnPbTe and a mixture thereof, and a quaternary compound selected from the group consisting of SnPbSSe, SnPbSeTe, and SnPbSTe and a mixture thereof. The IV group element may be selected from the group consisting of Si and Ge and a mixture thereof. The IV group compound may be a binary compound selected from the group consisting of SiC and SiGe and a mixture thereof.

The group IV element or compound may include a single element compound such as Si and Ge, a binary compound such as SiC and SiGe, or a combination thereof.

In this case, elements included in a multi-element compound such as a binary compound, a ternary compound, and a quaternary compound may be present in particles at a uniform or non-uniform concentration. That is, the chemical formula means the type of elements included in the compound, and an element ratio in the compound may be different. For example, AgInGaS2 may mean AgInₓGa₍₁₋ₓ₎S₂ (x is a real number between 0 and 1).

The shell of the quantum dot may include an oxide of a metal or a non-metal, a semiconductor compound, or a combination thereof.

For example, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO or a ternary compound such as MgAl₂O₄, CoFe₂O₄, NiFe₂O₄, and CoMn₂O₄ may be the oxide of the metal or non-metal, but embodiments according to the present disclosure are not limited thereto.

Further, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like may be the semiconductor compound, but embodiments according to the present disclosure are not limited thereto.

The quantum dot may have a full width at half maximum (FWHM) of a light emitting wavelength spectrum in a range of 45 nanometers (nm) (or about 45 nm) or less, preferably, 40 nm (or about 40 nm) or less, and more preferably, 30 nm (or about 30 nm) or less, and the color purity and the color reproducibility may be relatively improved in this range. Further, because a light emitted through this quantum dot is emitted in all directions, an optical viewing angle may be relatively improved.

A form of the quantum dot is not particularly limited to a form generally used in the field, and more particularly, a nanoparticle of a spherical shape, a pyramidal shape, a multi-arm shape, or a cubic shape, a nanotube, a nanowire, a nanofiber, a nanoplate particle, or the like may be used.

As described above, the quantum dot may adjust color of the emitted light depending on particle sizes, and accordingly, the quantum dot may have various light emitting colors such as blue, red, and green. As the particle sizes of the quantum dot decrease, a light having a short wavelength may be emitted. For example, in the quantum dots having the same core, the particle size of the quantum dot that emits a green light may be smaller than the particle size that emits a red light. Further, in the quantum dots having the same core, the particle size of the quantum dot that emits a blue light may be smaller than the particle size of the quantum dot that emits the green light. However, embodiments according to the present disclosure are not limited thereto, and even in the quantum dots having the same core, the particle size may be adjusted depending on a material forming the shell and a thickness of the shell. Meanwhile, when the quantum dots have various light emitting colors such as blue, red, and green, the quantum dots having different light emitting colors may have different core materials. The quantum dots may include ligands.

Examples of a green phosphor include a manganese-doped zinc silicon oxide-based phosphor (Zn2SiO4:Mn), an europium-doped strontium gallium sulfide-based phosphor (SrGa2S4:Eu), or an europium-doped barium silicon oxide chloride-based phosphor (Ba5Si2O7Cl4:Eu), but embodiments according to the present disclosure are not limited thereto.

Examples of the red phosphor include a praseodymium or aluminum-doped strontium titanium oxide-based phosphor (SrTiO3:Pr and SrTiO3:Al) or a praseodymium-doped calcium titanium oxide-based phosphor (CaTiO3:Pr), but embodiments according to the present disclosure are not limited thereto.

Meanwhile, the light control layer CCL may further include a scatterer. The first light control unit CCP1 may include the first quantum dot and the scatterer, and the second light control unit CCP2 may include the second quantum dot and the scatterer.

The scatterer may be an inorganic particle. For example, the scatterer may include at least one of TiO₂, ZrO₂, ZnO, Al₂O₃, SiO₂, or hollow silica. The scatterer may include one of TiO₂, ZrO₂, ZnO, Al₂O₃, SiO₂, and hollow silica or may be a mixture including two or more selected from TiO₂, ZrO₂, ZnO, Al₂O₃, SiO₂, and hollow silica.

Each of the first light control unit CCP1 and the second light control unit CCP2 may further include a base resin that disperses the quantum dot and the scatterer. According to some embodiments, the first light control unit CCP1 may include the first quantum dot and the scatterer dispersed inside the base resin, and the second light control unit CCP2 may include the second quantum dot and the scatterer dispersed inside the base resin.

The base resin, which is a medium in which the quantum dot and the scatterer are dispersed, may be made of various resin compositions that may generally be referred to as binders. For example, the base resin may be an acrylic resin, a urethane resin, a silicone resin, an epoxy resin, or the like. The base resin may be a transparent resin.

The planarization layer PL may be located under the light control units CCP1, CCP2, and CCP3 and the division pattern BMP. The planarization layer PL may serve as a protective layer that planarizes a lower surface of the light control member LCM and prevents or reduces inflow of external dust or the like.

FIG. 6 illustrates that the third light control unit CCP3 and the planarization layer PL are distinguished, which is to distinguish the arranged positions. The third light control unit CCP3 and the planarization layer PL may have an integral configuration. That is, the third light control unit CCP3 and the planarization layer PL may include the same material and may be formed in a single process. In an operation of forming the planarization layer PL, which will be described below, the third light control unit CCP3 may be formed integrally.

When viewed on a plane (e.g., in a plan view), an area of a part in which the first color filter CF1 is located may be the same as an area of the first light control unit CCP1. When viewed on a plane (e.g., in a plan view), an area of a part in which the second color filter CF2 is located may be the same as an area of the second light control unit CCP2. When viewed on a plane (e.g., in a plan view), an area of a part in which the selective absorption layer SA is located may be the same as an area of the third light control unit CCP3. That is, an area of the first pixel area PXA-R may be the same as an area of the first color filter CF1 and the area of the first light control unit CCP1, an area of the second pixel area PXA-G may be the same as an area of the second color filter CF2 and the area of the second light control unit CCP2, and an area of the third pixel area PXA-B may be the same as an area of the selective absorption layer SA and the area of the third light control unit CCP3.

Accordingly, in the light control member LCM according to some embodiments, because there is no alignment tolerance between the color filter layer CFL and the light control layer CCL, an aperture ratio may be relatively improved as compared to a case in which there is an alignment tolerance, and thus excellent light extraction efficiency may be exhibited.

FIGS. 7A to 7L are cross-sectional views illustrating some of operations of a method for manufacturing a display device according to some embodiments of the present disclosure. In description of FIGS. 7A to 7L, the same/similar reference numerals will be used for the same/similar components with reference to FIGS. 1 to 6, and duplicated descriptions thereof will be omitted.

A method of manufacturing a display device according to some embodiments of the present disclosure may include an operation of forming a first conductive layer, a buffer layer, and a second conductive layer on a base substrate including a display area and a non-display area around the display area, an operation of forming a first photoresist pattern by ashing a first photoresist layer using a mask, an operation of forming a conductive pattern, a buffer pattern, and a semiconductor pattern through a first etching operation of etching the first conductive layer, the buffer layer, and the second conductive layer using the first photoresist pattern, an operation of forming a preliminary gate insulating layer and a third conductive layer on the semiconductor pattern and the buffer pattern, an operation of forming a second photoresist pattern by ashing a second photoresist layer, and an operation of forming a gate electrode and a gate insulating layer through a second etching operation of etching the third conductive layer and the preliminary gate insulating layer using the second photoresist pattern.

Hereinafter, a configuration of the circuit layer DP-CL and a method of forming the first electrode EL1 of the display element layer DP-OL will be described through FIGS. 7A to 7L.

Referring to FIG. 7A, the method of manufacturing a display device according to the present disclosure may include an operation of forming a first conductive layer BML-I, a buffer layer BFL-I, and a second conductive layer AL-I on the base substrate BS and an operation of forming a first photoresist pattern PR1 by ashing a first photoresist layer using a first mask MK1 (or a mask). The base substrate BS may include the display area DA and the non-display area NDA around the display area DA.

The operation of forming the first conductive layer BML-I may include an operation of depositing one of molybdenum (Mo), aluminum (Al), chromium (Cr), gold (Au), titanium (Ti), nickel (Ni), neodymium (Nd), and copper (Cu) or an alloy thereof. The operation of forming the buffer layer BFL-I may include an operation of depositing an organic film including at least one of a silicon oxide layer or a silicon nitride layer. The operation of forming the second conductive layer AL-I may include an operation of depositing at least one of polysilicon, amorphous silicon, or a metal oxide.

After the first photoresist layer is formed on the second conductive layer AL-I, the first photoresist layer may be patterned using the first mask MK1, and the first photoresist pattern PR1 may be formed. The first mask MK1 may include a transmissive part TTA, a light shielding part NTA, and a semi-transmissive part HTA. The transmissive part TTA may transmit a light, and the light shielding part NTA may shield a light. Light transmittance of the semi-transmissive part HTA may be smaller than light transmittance of the transmissive part TTA and greater than light transmittance of the light shielding part NTA.

The first photoresist pattern PR1 patterned through the first mask MK1 may have a step. For example, the first photoresist pattern PR1 may include a first part P1 patterned by the light shielding part NTA and a second part P2 patterned by the semi-transmissive part HTA. A photoresist layer overlapping the transmissive part TTA may be removed. A height of the first part P1 may be greater than a height of the second part P2.

Thereafter, referring to FIGS. 7B to 7D, the method of manufacturing a display device according to the present disclosure may include an operation of forming the conductive pattern BML, the buffer pattern BFL, and the semiconductor pattern AL through the first etching operation of etching the first conductive layer BML-I, the buffer layer BFL-I, and the second conductive layer AL-I using the first photoresist pattern PR1. The first etching operation may include a (1-1)^{th} etching operation, a (1-2)^{th} etching operation, and a (1-3)^{th} etching operation. The (1-1)^{th} etching operation is described in FIG. 7B, the (1-2)^{th} etching operation is described in FIG. 7C, and the (1-3)^{th} etching operation is described in FIG. 7D.

Referring to FIG. 7B, the first etching operation may include the (1-1)^{th} etching operation of etching the second conductive layer AL-I. The second conductive layer AL-I may be etched to form the semiconductor pattern AL. The semiconductor pattern AL may be formed by etching further than a side surface of the first photoresist pattern PR1. The semiconductor pattern AL may overlap the first part P1 of the first photoresist pattern PR1. In this case, the (1-1)^{th} etching operation may correspond to wet etching. However, this is illustrative, and the (1-1)^{th} etching operation may correspond to metal dry etching.

Referring to FIG. 7C, the first etching operation may include an operation of etching the first photoresist pattern PR1 (see FIG. 7B) and the (1-2)^{th} etching operation of etching the buffer layer BFL-I. The first photoresist pattern PR1 may be etched in all directions. As a result, an etched first photoresist pattern PR1′ may be formed by not removing only a portion of the first part P1 (see FIG. 7B) of the first photoresist pattern PR1 and removing the other portion thereof. The operation of etching the first photoresist pattern PR1 may correspond to dry etching.

Thereafter, the buffer layer BFL-I may be etched using the semiconductor pattern AL as a mask, and the buffer pattern BFL may be formed from the buffer layer BFL-I. A side surface of the buffer pattern BFL may be formed to be aligned with a side surface of the semiconductor pattern AL. In this case, the (1-2)^{th} etching operation may correspond to dry etching. However, this is illustrative, and the (1-2)^{th} etching operation may correspond to inorganic film wet etching.

Referring to FIG. 7D, the first etching operation may include the (1-3)^{th} etching operation of etching the first conductive layer BML-I. The first conductive layer BML-I may be etched to form the conductive pattern BML. The conductive pattern BML may be formed by etching further than the side surface of the buffer pattern BFL. In this case, the (1-3)^{th} etching operation may correspond to wet etching. However, this is illustrative, and the (1-3)^{th} etching operation may correspond to metal dry etching. Thereafter, the etched first photoresist pattern PR1′ (see FIG. 7C) may be removed.

In the method of manufacturing a display device according to the present disclosure, the conductive pattern BML, the buffer pattern BFL, and the semiconductor pattern AL may be formed using one mask. Thus, the number of masks required for the method of manufacturing a display device may be reduced. Further, the display device DD formed according to the method of manufacturing a display device may include the conductive pattern BML, the source electrode SE and/or the drain electrode DE, and the gate electrode “G,” and thus resistance may be reduced, and a voltage drop phenomenon may be reduced or removed. Thus, the display device DD manufactured by a simplified manufacturing method and capable of implementing a high resolution may be provided.

Referring to FIG. 7E, the method of manufacturing a display device according to the present disclosure may include an operation of forming a preliminary gate insulating layer GI-I and a third conductive layer G-I on the semiconductor pattern AL and the buffer pattern BFL and an operation of forming a second photoresist pattern PR2 by ashing a second photoresist layer.

The operation of forming the preliminary gate insulating layer GI-I may include an operation of depositing a layer including an inorganic material, and the operation of the third conductive layer G-I may include an operation of depositing a layer including a conductive material.

After the second photoresist layer is formed on the third conductive layer G-I, the second photoresist layer may be patterned using a second mask MK2, and the second photoresist pattern PR2 may be formed. The second mask MK2 may include the transmissive part TTA and the light shielding part NTA. The transmissive part TTA may transmit a light, and the light shielding part NTA may shield a light. A photoresist layer overlapping the transmissive part TTA may be removed.

Thereafter, referring to FIGS. 7F and 7G, the method of manufacturing a display device according to the present disclosure may include an operation of forming the gate electrode “G” and the gate insulating layer GI through a second etching operation of etching the third conductive layer G-I and the preliminary gate insulating layer GI-I using the second photoresist pattern PR2. The second etching operation may include a (2-1)^{th} etching operation and a (2-2)^{th} etching operation. The (2-1)^{th} etching operation is described in FIG. 7F, and the (2-2)^{th} etching operation is described in FIG. 7G.

Referring to FIG. 7F, the second etching operation may include the (2-1)^{th} etching operation of etching the third conductive layer G-I. The third conductive layer G-I may be etched to form the gate electrode “G.” The gate electrode “G” may be formed by etching further than a side surface of the second photoresist pattern PR2. In this case, the (2-1)^{th} etching operation may correspond to wet etching. However, this is illustrative, and the (2-1)^{th} etching operation may correspond to metal dry etching.

Referring to FIG. 7G, the second etching operation may include an operation of etching the preliminary gate insulating layer GI-I (see FIG. 7F). The preliminary gate insulating layer GI-I may be etched using the second photoresist pattern PR2 as a mask, and the gate insulating layer GI may be formed from the preliminary gate insulating layer GI-I. A side surface of the gate insulating layer GI may protrude further than a side surface of the gate electrode “G.” In this case, the (2-2)^{th} etching operation may correspond to dry etching. However, this is illustrative, and the (2-2)^{th} etching operation may correspond to inorganic film wet etching. Thereafter, the second photoresist pattern PR2 (see FIG. 7F) may be removed.

According to some embodiments, the method of manufacturing a display device may further include an operation of N+ doping the semiconductor pattern AL exposed by the gate insulating layer GI through the (2-2)^{th} etching operation. The semiconductor pattern AL may be doped in the (2-2)^{th} etching operation corresponding to dry etching. As a result, the semiconductor pattern AL may include a first area having high conductivity and a second area having low conductivity. The first area may be doped with an N-type dopant, and the second area may be an undoped area or an area doped at a lower concentration than that of the first area. The semiconductor pattern AL may include the source area “S,” the drain area “D,” and the channel area “A.” The drain area “D” may be spaced apart from the source area “S,” and the channel area “A” may be formed between the source area “S” and the drain area “D.” The first area may be the source area “S” or the drain area “D” of the semiconductor pattern AL, and the second area may be the channel area “A.”

Referring to FIG. 7H, the method of manufacturing a display device according to the present disclosure may further include an operation of forming a first preliminary insulating layer 10-I covering the gate electrode “G” and an operation of forming a third photoresist pattern PR3 by ashing a third photoresist layer.

The operation of forming the first preliminary insulating layer 10-I may include an operation of depositing a layer including an inorganic material. After the third photoresist layer is formed on the first preliminary insulating layer 10-I, the third photoresist layer may be patterned using a third mask MK3, and the third photoresist pattern PR3 may be formed. The third mask MK3 may include the transmissive part TTA and the light shielding part NTA. The transmissive part TTA may transmit a light, and the light shielding part NTA may shield a light. A photoresist layer overlapping the transmissive part TTA may be removed.

Thereafter, referring to FIG. 7I, the method of manufacturing a display device according to the present disclosure may further include an operation of forming the first insulating layer 10 through a third etching operation of etching the first preliminary insulating layer 10-I using the third photoresist pattern PR3. In this case, the third etching operation may correspond to dry etching. However, this is illustrative, and the third etching operation may correspond to inorganic film wet etching. Thereafter, the third photoresist pattern PR3 (see FIG. 7H) may be removed.

Referring to FIG. 7J, the method of manufacturing a display device according to the present disclosure may further include an operation of forming a third conductive layer in contact with the semiconductor pattern AL on the first insulating layer 10, an operation of forming a fourth photoresist pattern PR4 by ashing a fourth photoresist layer, and an operation of forming the source electrode SE and the drain electrode DE in contact with the semiconductor pattern AL through a fourth etching operation of etching the third conductive layer using the fourth photoresist pattern PR4.

The operation of forming the third conductive layer may include an operation of depositing a layer including a conductive material. After the fourth photoresist layer is formed on the third conductive layer, the fourth photoresist layer may be patterned using a fourth mask MK4, and the fourth photoresist pattern PR4 may be formed. The fourth mask MK4 may include the transmissive part TTA and the light shielding part NTA. The transmissive part TTA may transmit a light, and the light shielding part NTA may shield a light. A photoresist layer overlapping the transmissive part TTA may be removed.

Electrodes may be formed through the fourth etching operation, and the electrodes may include the source electrode SE in contact with the source area “S” of the semiconductor pattern AL and the drain electrode DE in contact with the drain area “D” of the semiconductor pattern AL. In this case, the fourth etching operation may correspond to wet etching. However, this is illustrative, and the fourth etching operation may correspond to metal dry etching. Thereafter, the fourth photoresist pattern PR4 may be removed.

The operation of forming the source electrode SE and the drain electrode DE in contact with the semiconductor pattern AL may include an operation of forming the pad PD in the non-display area NDA. That is, the pad PD located on the first insulating layer 10 in the non-display area NDA may include the same material as the source electrode SE and/or the drain electrode DE and may be formed through the same process.

Further, referring to FIGS. 7F and 7J, the operation of forming the gate electrode “G” and the gate insulating layer GI may include an operation of forming the first conductive pattern C1, and the operation of forming the source electrode SE and the drain electrode DE may include an operation of forming the second conductive pattern C2. That is, the first conductive pattern C1 may include the same material as the gate electrode “G,” and may be formed through the same process, and the second conductive pattern C2 may include the same material as the source electrode SE and/or the drain electrode DE and may be formed through the same process.

Referring to FIG. 7K, the method of manufacturing a display device according to the present disclosure may further include an operation of forming a second preliminary insulating layer covering the first insulating layer 10, the source electrode SE, and the drain electrode DE, an operation of forming a third preliminary insulating layer on the second preliminary insulating layer, and an operation of forming a fifth photoresist pattern PR5 by ashing a fifth photoresist layer.

The operation of forming the second preliminary insulating layer may include an operation of depositing an inorganic material. The operation of forming the third preliminary insulating layer may include an operation of depositing an organic material. After the fifth photoresist layer is formed on the third preliminary insulating layer, the fifth photoresist pattern PR5 may be formed using a fifth mask.

Thereafter, the method of manufacturing a display device according to the present disclosure may further include an operation of forming the second insulating layer 20 and the third insulating layer 30 through a fifth etching operation of etching the second preliminary insulating layer and the third preliminary insulating layer using the fifth photoresist pattern PR5. The fifth etching operation may correspond to dry etching. However, this is illustrative, and the fifth etching operation may correspond to wet etching.

Thereafter, referring to FIG. 7L, the method of manufacturing a display device according to the present disclosure may include an operation of forming the light emitting element OLED (see FIG. 6) on the third insulating layer 30. The light emitting element OLED may include the first electrode EL1, the light emitting layer EML (see FIG. 6), and the second electrode EL2 (see FIG. 6). FIG. 7L illustratively illustrates that only the first electrode EL1 among the light emitting element OLED is formed. An operation of forming the first electrode EL1 may include an operation of depositing an anode layer, an operation of forming a photoresist pattern by ashing a photoresist layer, and an operation of patterning the first electrode EL1 using the photoresist pattern.

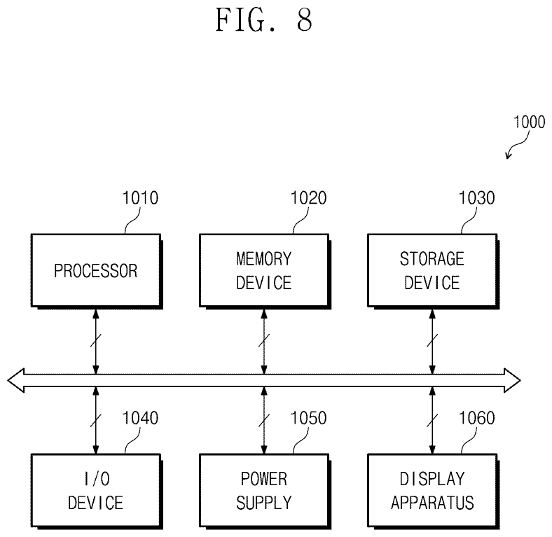

FIG. 8 is a block diagram illustrating an electronic device according to some embodiments of the present disclosure.

Referring to FIGS. 8 and 1, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a home appliance, a tablet PC, a vehicle display, a computer monitor, a notebook computer, an entertainment device like a head-mounted display device, etc. In addition, the electronic device 1000 may be a television, a monitor, a notebook computer, or a tablet. In addition, the electronic device 1000 may be a car.

The display device according to the embodiments may be applied to a device included in a computer, a notebook, a mobile phone, a smartphone, a smart pad, a PMP, a PDA, an MP3 player, or the like.

According to the above description, a conductive pattern, a buffer pattern, and a semiconductor pattern may be formed using one mask. Thus, the number of masks required for the method of manufacturing a display device may be reduced. Further, the display device formed according to the method of manufacturing a display device may include a conductive pattern, a source electrode and/or a drain electrode, and a gate electrode, and thus resistance may be reduced, and a voltage drop phenomenon may be reduced or removed. Thus, the display device manufactured by a simplified manufacturing method and capable of implementing a high resolution may be provided.

Although the description has been made above with reference to aspects of some embodiments of the present disclosure, it may be understood that those skilled in the art or those having ordinary knowledge in the art may variously modify and change the present disclosure without departing from the spirit and technical scope of the present disclosure described in the appended claims. Thus, the technical scope of embodiments according to the present disclosure are not limited to the detailed description of the specification but should be defined by the appended claims, and their equivalents.

What is claimed is:

1. A method of manufacturing a display device, the method comprising:
forming a first conductive layer, a buffer layer, and a second conductive layer on a base substrate including a display area and a non-display area around the display area;
forming a first photoresist pattern by ashing a first photoresist layer using a mask;
forming a conducive pattern, a buffer pattern, and a semiconductor pattern through a first etching operation of etching the first conductive layer, the buffer layer, and the second conductive layer using the first photoresist pattern;
forming a preliminary gate insulating layer and a third conductive layer on the semiconductor pattern and the buffer pattern;
forming a second photoresist pattern by ashing a second photoresist layer; and
forming a gate electrode and a gate insulating layer through a second etching operation of etching the third conductive layer and the preliminary gate insulating layer using the second photoresist pattern.

2. The method of claim 1, wherein the first etching operation includes a (1-1)^{th}etching operation of etching the second conductive layer, and the (1-1)^{th} etching operation corresponds to wet etching.

3. The method of claim 1, wherein the first etching operation includes:
an operation of etching the first photoresist pattern; and
a (1-2)^{th} etching operation of etching the buffer layer, and
wherein the (1-2)^{th} etching operation corresponds to dry etching.

4. The method of claim 1, wherein the first etching operation includes a (1-3)^{th}etching operation of etching the first conductive layer, and the (1-3)^{th} etching operation corresponds to wet etching.

5. The method of claim 1, wherein the mask includes a transmissive part configured to transmit a light, a light shielding part configured to shield a light, and a semi-transmissive part having light transmittance smaller than that of the transmissive part, and
wherein the first photoresist pattern includes a first part patterned by the light shielding part and a second part patterned by the semi-transmissive part, and a height of the first part is greater than a height of the second part, and
the semiconductor pattern overlaps the first part of the first photoresist pattern.

6. The method of claim 1, wherein the second etching operation includes a (2-1)^{th} etching operation of etching the third conductive layer and a (2-2)^{th} etching operation of etching the preliminary gate insulating layer, the (2-1)^{th} etching operation corresponds to wet etching, and the (2-2)^{th} etching operation corresponds to dry etching.

7. The method of claim 6, further comprising:
n+ doping the semiconductor pattern exposed by the gate insulating layer through the (2-2)^{th} etching operation.

8. The method of claim 1, further comprising:
forming a first preliminary insulating layer configured to cover the gate electrode;
forming a third photoresist pattern by ashing a third photoresist layer; and
forming a first insulating layer through a third etching operation of etching the first preliminary insulating layer using the third photoresist pattern.

9. The method of claim 8, wherein the third etching operation corresponds to dry etching.

10. The method of claim 8, further comprising:
forming the third conductive layer contacting the semiconductor pattern on the first insulating layer;
forming a fourth photoresist pattern by ashing a fourth photoresist layer; and
forming a source electrode and a drain electrode contacting the semiconductor pattern through a fourth etching operation of etching the third conductive layer using the fourth photoresist pattern.

11. The method of claim 10, wherein the forming of the source electrode and the drain electrode contacting the semiconductor pattern includes forming a pad on the non-display area.

12. The method of claim 10, wherein the fourth etching operation corresponds to wet etching.

13. The method of claim 10, wherein the forming of the gate electrode and the gate insulating layer includes forming a first conductive pattern,
wherein the forming of the source electrode and the drain electrode includes forming a second conductive pattern, and
wherein the first conductive pattern and the second conductive pattern form a capacitor.

14. The method of claim 10, further comprising:
forming a second preliminary insulating layer configured to cover the first insulating layer, the source electrode, and the drain electrode;
forming a third preliminary insulating layer on the second preliminary insulating layer;
forming a fifth photoresist pattern by ashing a fifth photoresist layer; and
forming a second insulating layer and a third insulating layer through a fifth etching operation of etching the second preliminary insulating layer and the third preliminary insulating layer using the fifth photoresist pattern.

15. The method of claim 14, wherein the forming of the second preliminary insulating layer includes depositing an inorganic material, and
wherein the forming of the third preliminary insulating layer includes depositing an organic material.

18. The method of claim 14, wherein the fifth etching operation corresponds to dry etching.

17. The method of claim 14, further comprising:
forming a light emitting element including a first electrode, a light emitting layer, and a second electrode on the third insulating layer.

18. A display device comprising:
a base substrate;
a conductive pattern on the base substrate;
a buffer pattern on the conductive pattern;
a transistor on the buffer pattern and including a semiconductor pattern, a source electrode, a drain electrode, and a gate electrode; and
a light emitting element including a first electrode, a light emitting layer, and a second electrode on the transistor and electrically connected to the transistor,
wherein the semiconductor pattern includes a source area contacting the source electrode, a drain area spaced apart from the source area and contacting the drain electrode, and a channel area between the source area and the drain area, and
wherein, in a plan view, the semiconductor pattern overlaps the buffer pattern.

19. The display device of claim 18, further comprising:
a first conductive pattern including a same material as the source electrode and the drain electrode and formed through a same process; and
a second conductive pattern including a same material as the gate electrode and formed through a same process,
wherein the first conductive pattern and the second conductive pattern form a capacitor.

20. An electronic device comprising:
a display device configured to display an image; and
a processor configured to control the display device to display the image,
wherein the display device comprising:
a base substrate;
a conductive pattern on the base substrate;
a buffer pattern on the conductive pattern;
a transistor on the buffer pattern and including a semiconductor pattern, a source electrode, a drain electrode, and a gate electrode; and
a light emitting element including a first electrode, a light emitting layer, and a second electrode on the transistor and electrically connected to the transistor,
wherein the semiconductor pattern includes a source area contacting the source electrode, a drain area spaced apart from the source area and contacting the drain electrode, and a channel area formed between the source area and the drain area, and
wherein, in a plan view, the semiconductor pattern overlaps the buffer pattern.
